(19) United States
(12) Patent Application Publication
(10) Pub. No.: US 2014/0029369 A1
(43) Pub. Date: Jan. 30, 2014

(54) MEMORY DEVICE, CONTROLLER, AND WRITE CONTROL METHOD

(71) Applicant: KABUSHIKI KAISHA TOSHIBA, Tokyo (JP)

(72) Inventors: Susumu YAMAZAKI, Yokohama (JP); Kenji YOSHIDA, Kamakura (JP)

(73) Assignee: KABUSHIKI KAISHA TOSHIBA, Tokyo (JP)

(21) Appl. No.: 13/777,992

(22) Filed: Feb. 26, 2013

(30) Foreign Application Priority Data
Jul. 25, 2012 (JP) P2012-164953

(51) Int. Cl. G11C 16/10

(52) U.S. Cl. CPC G11C 16/10
USPC 365/230.03

(57) ABSTRACT

According to one embodiment, a storage device includes a buffer memory, a write controller, a nonvolatile memory, and bank writing modules. Data buffer areas are set in the buffer memory. The write controller sequentially writes data transmitted from a host to the data buffer areas. Banks are set in the nonvolatile memory. The write controller writes data transmitted from the host to a data buffer area in the data buffer areas from which first data written to the data buffer area is read when one of the bank writing modules reads the first data. Each bank writing module reads second data from one of the data buffer areas independently of data write processing statuses of another bank writing module, and writes the second data to a corresponding bank.

### CROSS-REFERENCE TO RELATED APPLICATIONS

This application is based upon and claims the benefit of priority from Japanese Patent Application No. 2012-164953, filed Jul. 25, 2012, the entire contents of which are incorporated herein by reference.

### FIELD

Embodiments described herein relate generally to a memory device that writes data to a nonvolatile memory by using a buffer memory, and to a controller and write control method.

### BACKGROUND

To increase the data transfer rate, a DRAM performs memory interleaving by which a plurality of banks are simultaneously accessed.

On the other hand, the data write processing times of banks of a nonvolatile memory are greatly different in some cases. When transferring data from a buffer memory to a plurality of banks of a nonvolatile memory, therefore, it is sometimes impossible to perform efficient write control because a bank having a low data write speed prevents a write operation to a bank having a high data write speed.

### BRIEF DESCRIPTION OF THE DRAWINGS

FIG. 1 is a block diagram showing an example of the arrangement of a memory device of an embodiment.

FIG. 2 is a block diagram showing an example of the arrangement of a controller of the embodiment.

FIG. 3 is a view showing an example of the arrangement of a host buffer controller and flash memory buffer controller of the embodiment.

FIG. 4 is a flowchart for explaining an example of the operation of the host buffer controller of the embodiment.

FIG. 5 is a flowchart for explaining an example of the operation of the flash memory buffer controller of the embodiment.

FIG. 6 is a view showing an example of the host buffer controller, the flash memory buffer controller, a buffer memory, and a NAND flash memory in the initial state of writing.

FIG. 7 is a view for explaining the procedure of processing after data D1 is written to the first block of bank 1.

FIG. 8 is a view for explaining the procedure of the processing after data D1 is written to the first block of bank 1.

FIG. 9 is a view for explaining the procedure of the processing after data D1 is written to the first block of bank 1.

FIG. 10 is a view for explaining the procedure of the processing after data D1 is written to the first block of bank 1.

FIG. 11 is a view showing a state after data D11 is written to the third block of bank 3.

FIG. 12 is a view for explaining the procedure of processing after data D11 is written to the third block of bank 3.

FIG. 13 is a view for explaining the procedure of the processing after data D11 is written to the third block of bank 3.

FIG. 14 is a view for explaining the procedure of the processing after data D11 is written to the third block of bank 3.

FIG. 15 is a view for explaining the procedure of the processing after data D11 is written to the third block of bank 3.

FIG. 16 is a view for explaining the procedure of the processing after data D11 is written to the third block of bank 3.

FIG. 17 is a view for explaining the procedure of processing after data D10 is written to the third block of bank 2.

FIG. 18 is a view for explaining the procedure of the processing after data D10 is written to the third block of bank 2.

FIG. 19 is a view for explaining the procedure of the processing after data D10 is written to the third block of bank 2.

FIG. 20 is a view for explaining the procedure of the processing after data D10 is written to the third block of bank 2.

FIG. 21 is a view for explaining the procedure of the processing after data D10 is written to the third block of bank 2.

FIG. 22 is a view for explaining the procedure of processing after data D13 is written to the fourth block of bank 1.

FIG. 23 is a view for explaining the procedure of the processing after data D13 is written to the fourth block of bank 1.

FIG. 24 is a view for explaining the procedure of the processing after data D13 is written to the fourth block of bank 1.

FIG. 25 is a view for explaining the procedure of the processing after data D13 is written to the fourth block of bank 1.

FIG. 26 is a view for explaining the procedure of the processing after data D13 is written to the fourth block of bank 1.

FIG. 27 is a view for explaining the procedure of processing after data D0 is written to the first block of bank 0.

FIG. 28 is a view for explaining the procedure of the processing after data D0 is written to the first block of bank 0.

FIG. 29 is a view for explaining the procedure of the processing after data D0 is written to the first block of bank 0.

FIG. 30 is a view for explaining the procedure of the processing after data D0 is written to the first block of bank 0.

FIG. 31 is a view for explaining the procedure of the processing after data D0 is written to the first block of bank 0.

FIG. 32 is a view for explaining the procedure of the processing after data D0 is written to the first block of bank 0.

### DETAILED DESCRIPTION

In general, according to one embodiment, a storage device comprises a buffer memory, a first write controller, a nonvolatile memory in which banks are set, and a second write controller. Data buffer areas are set in the buffer memory. The first write controller is configured to sequentially write data transmitted from a host to the data buffer areas. The second write controller comprising bank writing modules corresponding to the banks, each bank writing module reading data written to one of the data buffer areas, and writing the read data to a corresponding bank of the nonvolatile memory. The first write controller is configured to write data transmitted from the host to a data buffer area in the data buffer areas from which first data written to the data buffer area is read when one of the bank writing modules reads the first data. Each bank writing module is configured to read second data from one of the data buffer areas independently of data write processing statuses of another bank writing module, and to write the second data to a corresponding bank.

A memory device can be implemented as a hybrid-hard disk drive (H-HDD).

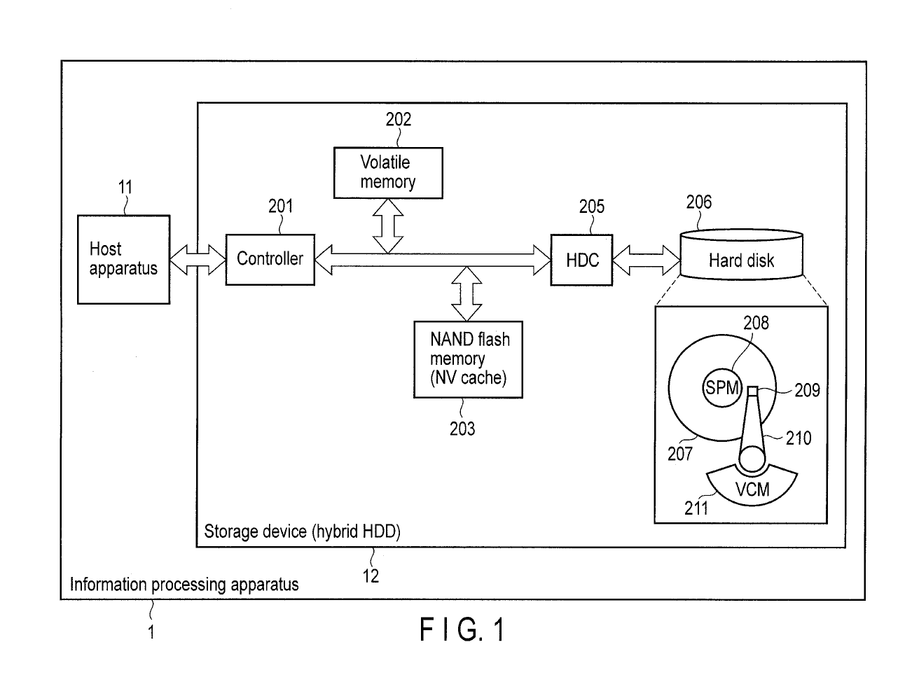

FIG. 1 is a block diagram showing the arrangement of the memory device.

This memory device is implemented as a storage device 12 conformant with, for example, the AT Attachment (ATA) controller standards. The storage device 12 functions as, for example, a hybrid hard disk drive (hybrid HDD). The hybrid HDD is a disk drive including a hard disk (disk storage medium), and a nonvolatile memory that functions as a cache of the disk storage medium. A NAND flash memory or the like is used as the nonvolatile memory.

The storage device 12 is a drive device that functions as an external memory of an information processing apparatus 1 such as a server or personal computer. A host apparatus 11 and the storage device 12 are installed in the main body of the information processing apparatus 1. The host apparatus 11 is a core unit of the information processing apparatus 1, and includes a CPU for executing various programs, and a memory. The storage device 12 is connected to the host apparatus 11 via an ATA interface such as a serial ATA.

The storage device 12 includes a controller 201, volatile memory 202, NAND flash memory 203, hard disk controller (HDC) 205, and hard disk 206. The controller 201 is a microprocessor for controlling each unit in the storage device 12. The controller 201 includes an ATA controller as a host interface that communicates with the host apparatus 11 via the ATA interface. The HDC 205 is a controller for controlling the hard disk 206.

The nonvolatile memory 202 is, for example, a DRAM.

The hard disk 206 is a disk storage medium. More specifically, the hard disk 206 includes a disk storage medium 207, spindle motor (SPM) 208, head 209, actuator 210, and voice coil motor (VCM) 211. The SPM 208 rotates the disk storage medium 207. The actuator 210 and VCM 211 form a head driving mechanism for moving the head 209 in the radial direction of the disk storage medium 207.

The volatile memory 202 functions as a data buffer for temporarily storing write data from the host apparatus 11, or read data to be read to the host apparatus 11. The volatile memory 202 will also be referred to as a buffer memory 202 in some cases hereinafter. The NAND flash memory 203 is a cache memory (nonvolatile cache memory) that functions as a cache of the hard disk (disk storage medium) 206. The NAND flash memory 203 stores data read from the hard disk 206. Also, the NAND flash memory 203 can constantly store a specific data set to be transferred at high speed to the host apparatus 11. That is, software (for example, the kernel of an operating system, device drivers, and application programs) and user data are normally entirely stored in only the hard disk 206. In this embodiment, however, copies of some of the software or copies of some of the user data stored in the hard disk 206 can constantly be stored in the NAND flash memory 203, as data to be read at high speed to the host apparatus 11. Data constantly stored in the NAND flash memory 203 will also be called pinned data in some cases.

The host apparatus 11 can designate which data in the hard disk 206 is to be stored in the NAND flash memory 203. The controller 201 loads data corresponding to each logical block address (LBA) designated by the host apparatus 11, from the hard disk 206 to the NAND flash memory 203. The loaded data can constantly be held on the NAND flash memory 203. Also, data read from the hard disk 206 in response to each read command issued from the host apparatus 11 in a predetermined period such as a period from the start to completion of booting the operating system can be stored as pinned data in the NAND flash memory 203.

The data read rate of the NAND flash memory 203 is higher than that of the hard disk 206. When the NAND flash memory 203 functions as a cache of the hard disk 206, therefore, the response performance of the storage device 12 can be improved.

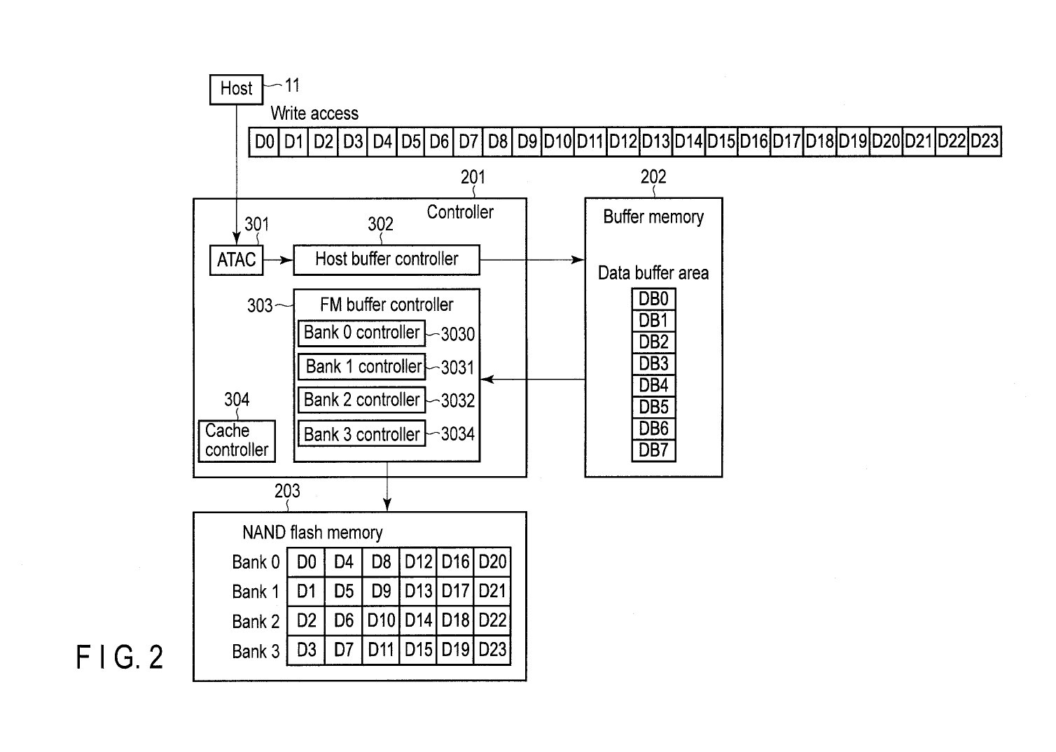

Next, the arrangement of the controller 201 will be explained with reference to FIG. 2. FIG. 2 is a block diagram showing the arrangement of the controller 201.

The controller 201 includes an ATA controller (ATAC) 301, host buffer controller 302, flash memory buffer controller (FM buffer controller) 303, and cache controller 304. The functions of the ATAC 301, host buffer controller 302, FM buffer controller 303, cache controller 304, and the like of the controller 201 are integrated on one semiconductor chip, and the controller 201 is implemented by a system-on-a-chip (SoC). The ATAC 301 is a host interface for communicating with the host apparatus 11 via the ATA interface. The host buffer controller 302 sequentially stores, for example, write access data of the host to a plurality of data buffer areas set in the buffer memory 202. The FM buffer controller 303 includes a bank 0 controller 3030, bank 1 controller 3031, bank 2 controller 3032, and bank 3 controller 3033. The bank 0 controller 3030, bank 1 controller 3031, bank 2 controller 3032, and bank 3 controller 3033 write data in parallel to four banks set in the NAND flash memory 203, or read data in parallel from the four banks.

As an example, an operation when the host performs write access for data including data D0 to D23 will be explained below. The bank 0 controller 3030 sequentially writes data D0, D4, D8, D12, D16, and D20 to bank 0. The bank 1 controller 3031 sequentially writes data D1, D5, D9, D13, D17, and D21 to bank 1. The bank 2 controller 3032 sequentially writes data D2, D6, D10, D14, D18, and D22 to bank 2. The bank 3 controller 3033 sequentially writes data D3, D7, D11, D15, D19, and D23 to bank 3.

The cache controller 304 determines whether data designated by a medium access command (for example, a data read command or data write command) from the host apparatus 11 is stored in the NAND flash memory 203, and selectively accesses the NAND flash memory 203 or hard disk 206 in accordance with the determination result.

If the data corresponding to an LBA contained in the medium access command exists in the NAND flash memory 203 (cache hit), the cache controller 304 executes access (read access or write access) to the NAND flash memory 203, and does not access the hard disk 206.

On the other hand, if the data corresponding to the LBA contained in the medium access command does not exist in the NAND flash memory 203 (cache miss), the cache controller 304 accesses the hard disk 206. If the medium access command is a read command, the data is read from the hard disk 206. The read data is stored in the NAND flash memory 203, and transmitted to the host apparatus 11 as well.

The cache controller 304 also executes a process by which a predetermined data set stored in the hard disk 206 is stored as pinned data in the NAND flash memory 203. For example, the cache controller 304 can store, for example, a data set belonging to a specific LBA range, a data set having a high use frequency, or a data set read from the hard disk 206 during the boot period, as pinned data in the NAND flash memory 203.

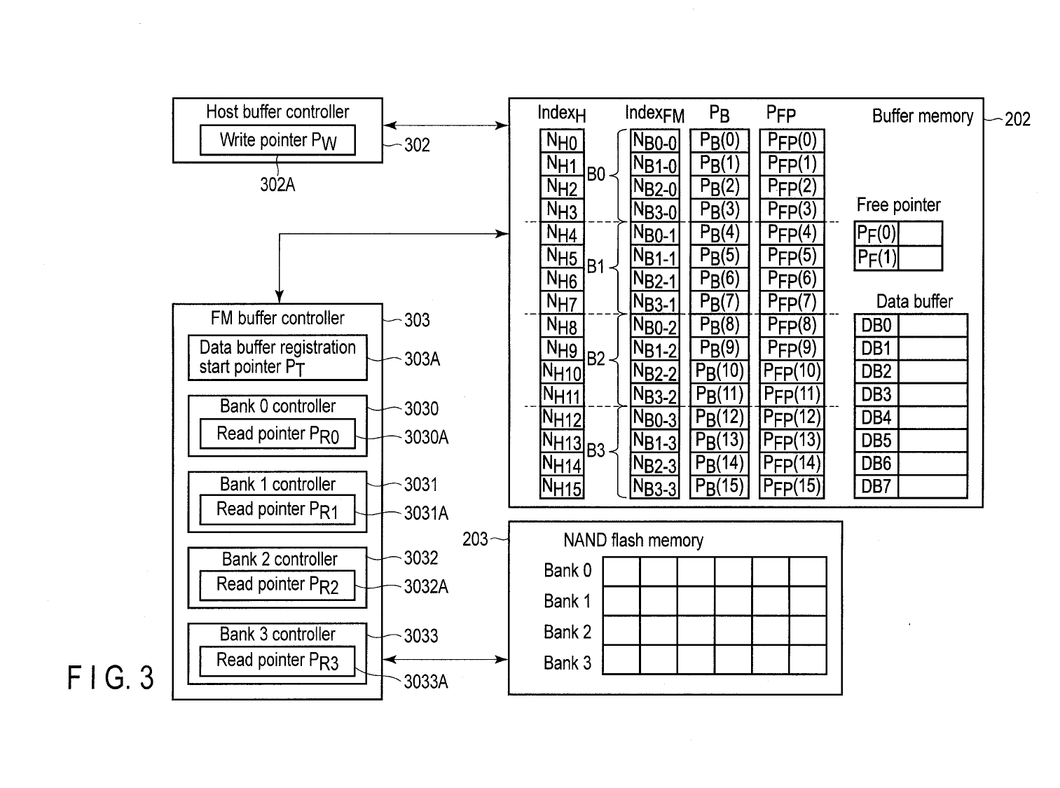

FIG. 3 is a view showing the arrangement of the host buffer controller 302 and FM buffer controller 303. The operation of the host buffer controller 302 and FM buffer controller 303 will be explained below with reference to FIG. 3.

The host buffer controller 302 includes a memory unit 302A for storing a write pointer P_{W}. The FM buffer controller 303 includes a memory unit 303A for storing a data buffer registration start pointer P_{T}. The bank 0 controller 3030 includes a memory unit 3030A for storing a read pointer P_{R0}. The bank 1 controller 3031 includes a memory unit 3031A for storing a read pointer P_{R1}. The bank 2 controller 3032 includes a memory unit 3032A for storing a read pointer P_{R2}. The bank 3 controller 3033 includes a memory unit 3033A for storing a read pointer P_{R3}.

A host index storage area Index_{H} is set in the buffer memory 202. Host index numbers N_{H0} to N_{H15} are stored in the host index storage area Index_{H}.

The number of host indices stored in the host index storage area Index_{H} is an integral multiple of the number of banks. In this embodiment, 16 host indices, which is four times the number of banks, are stored in the host index storage area Index_{H}.

A flash memory index storage area Index_{FM} is set in the buffer memory 202. Flash memory (FM) index numbers N_{B0-0}, N_{B1-0}, N_{B2-0}, N_{B3-0}, N_{B0-1}, N_{B1-1}, N_{B2-1}, N_{B3-1}, N_{B0-2}, N_{B1-2}, N_{B2-2}, N_{B3-2}, N_{B0-3}, N_{B1-3}, N_{B0-3}, and N_{B3-3} are stored in the flash memory index storage area Index_{FM}.

FM index numbers N_{B0-0}, N_{B1-0}, N_{B2-0}, N_{B3-0}, N_{B0-1}, N_{B1-1}, N_{B2-1}, N_{B3-1}, N_{B0-2}, N_{B1-2}, N_{B2-2}, N_{B3-2}, N_{B0-3}, N_{B1-3}, N_{B2-3}, and N_{B3-3} are divisionally stored in blocks B0, B1, B2, and B3.

FM index numbers N_{B0-M} (M=0, 1, 2, and 3) corresponding to the bank 0 controller 3030, FM index numbers N_{B1-M} (M=0, 1, 2, and 3) corresponding to the bank 1 controller 3031, FM index numbers N_{B2-M} (M=0, 1, 2, and 3) corresponding to the bank 2 controller 3032, and FM index numbers N_{B3-M} (M=0, 1, 2, and 3) corresponding to the bank 3 controller 3033 are stored in these blocks.

Write pointer P_{W}=H0 and data buffer registration start pointer P_{T}=H0 indicate host index number N_{H0}. Write pointer P_{W}=H1 and data buffer registration start pointer P_{T}=H1 indicate host index number N_{H1}. Write pointer P_{W}=H2 and data buffer registration start pointer P_{T}=H2 indicate host index number N_{H2}. Write pointer P_{W}=H3 and data buffer registration start pointer P_{T}=H3 indicate host index number N_{H3}.

Write pointer P_{W}=H4 and data buffer registration start pointer P_{T}=H4 indicate host index number N_{H4}. Write pointer P_{W}=H5 and data buffer registration start pointer P_{T}=H5 indicate host index number N_{H5}. Write pointer P_{W}=H6 and data buffer registration start pointer P_{T}=H6 indicate host index number N_{H6}. Write pointer P_{W}=H7 and data buffer registration start pointer P_{T}=H7 indicate host index number N_{H7}.

Write pointer P_{W}=H8 and data buffer registration start pointer P_{T}=H8 indicate host index number N_{H8}. Write pointer P_{W}=H9 and data buffer registration start pointer P_{T}=H9 indicate host index number N_{H9}. Write pointer P_{W}=H10 and data buffer registration start pointer P_{T}=H10 indicate host index number N_{H10}. Write pointer P_{W}=H11 and data buffer registration start pointer P_{T}=H11 indicate host index number N_{H11}.

Write pointer P_{W}=H12 and data buffer registration start pointer P_{T}=H12 indicate host index number N_{H12}. Write pointer P_{W}=H13 and data buffer registration start pointer P_{T}=H13 indicate host index number N_{H13}. Write pointer P_{W}=H14 and data buffer registration start pointer P_{T}=H14 indicate host index number N_{H14}. Write pointer P_{W}=H15 and data buffer registration start pointer P_{T}=H15 indicate host index number N_{H15}.

Read pointer P_{R0}=B0-0 indicates flash memory index number N_{B0-0}. Read pointer P_{R0}=B0-1 indicates flash memory index number N_{B0-1}. Read pointer P_{R0}=B0-2 indicates flash memory index number N_{B0-2}. Read pointer P_{R0}=B0-3 indicates flash memory index number N_{B0-3}.

Read pointer P_{R1}=B1-0 indicates flash memory index number N_{B1-0}. Read pointer P_{R1}=B1-1 indicates flash memory index number N_{B1-1}. Read pointer P_{R1}=B1-2 indicates flash memory index number N_{B1-2}. Read pointer P_{R1}=B1-3 indicates flash memory index number N_{B1-3}.

Read pointer P_{R2}=B2-0 indicates flash memory index number N_{B2-0}. Read pointer P_{R2}=B2-1 indicates flash memory index number N_{B2-1}. Read pointer P_{R2}=B2-2 indicates flash memory index number N_{B2-2}. Read pointer P_{R2}=B2-3 indicates flash memory index number N_{B2-3}.

Read pointer P_{R3}=B3-0 indicates flash memory index number N_{B3-0}. Read pointer P_{R3}=B3-1 indicates flash memory index number N_{B3-1}. Read pointer P_{R3}=B3-2 indicates flash memory index number N_{B3-2}. Read pointer P_{R3}=B3-3 indicates flash memory index number N_{B3-3}.

A buffer pointer area P_{B} is set in the buffer memory 202. Buffer pointer storage areas P_{B}(0) to P_{B}(15) are set in the buffer pointer area P_{B}. Data buffer numbers corresponding to data buffer areas can be stored in some of buffer pointer storage areas P_{B}(0) to P_{B}(15).

A free pointer/pointer area P_{FP} is set in the buffer memory 202. Free pointer/pointer area P_{FP}(0) to P_{FP}(15) are set in the free pointer/pointer area P_{FP}. A free pointer area P_{F} is set in the buffer memory 202. Free pointer storage areas P_{F}(0) and P_{F}(1) are set in the free pointer area P_{F}. Free pointer numbers indicating the free pointer storage areas can be stored in free pointer/pointer storage areas P_{FP}(0) to P_{FP}(15). Data buffer numbers corresponding to data buffer areas can be stored in the free pointer storage areas.

Host index number N_{H0} and FM index number N_{B0-0} are associated with buffer pointer storage area P_{B}(0). Buffer pointer storage area P_{B}(0) is associated with free pointer/pointer storage area P_{FP}(0). Host index number N_{H1} and FM index number N_{B1-0} are associated with buffer pointer storage area P_{B}(1). Buffer pointer storage area P_{B}(1) is associated with free pointer/pointer storage area P_{FP}(1). Host index number N_{H2} and FM index number N_{B2-0} are associated with buffer pointer storage area P_{B}(2). Buffer pointer storage area P_{B}(2) is associated with free pointer/pointer storage area P_{FP}(2). Host index number N_{H3} and FM index number N_{B3-0} are associated with buffer pointer storage area P_{B}(3). Buffer pointer storage area P_{B}(3) is associated with free pointer/pointer storage area P_{FP}(3).

Host index number N_{H4} and FM index number N_{B0-1} are associated with buffer pointer storage area P_{B}(4). Buffer pointer storage area P_{B}(4) is associated with free pointer/pointer storage area P_{FP}(4). Host index number N_{H5} and FM index number N_{B1-1} are associated with buffer pointer storage area P_{B}(5). Buffer pointer storage area P_{B}(5) is associated with free pointer/pointer storage area P_{FP}(5). Host index number N_{H6} and FM index number N_{B2-1} are associated with buffer pointer storage area P_{B}(6). Buffer pointer storage area P_{B}(6) is associated with free pointer/pointer storage area P_{FP}(6). Host index number N_{H7} and FM index number N_{B3-1} are associated with buffer pointer storage area P_{B}(7). Buffer pointer storage area P_{B}(7) is associated with free pointer/pointer storage area P_{FP}(7).

Host index number N_{H8} and FM index number N_{B0-2} are associated with buffer pointer storage area P_{B}(8). Buffer pointer storage area P_{B}(8) is associated with free pointer/pointer storage area P_{FP}(8). Host index number N_{H9} and FM index number N_{B1-2} are associated with buffer pointer storage area P_{B}(9). Buffer pointer storage area P_{B}(9) is associated with free pointer/pointer storage area P_{FP}(9). Host index number N_{H10} and FM index number N_{B2-2} are associated with buffer pointer storage area P_{B}(10). Buffer pointer storage area P_{B}(10) is associated with free pointer/pointer storage area P_{FP}(10). Host index number N_{H11} and FM index number N_{B3-2} are associated with buffer pointer storage area P_{B}(11). Buffer pointer storage area P_{B}(11) is associated with free pointer/pointer storage area P_{FP}(11).

Host index number N_{H12} and FM index number N_{B0-3} are associated with buffer pointer storage area P_{B}(12). Buffer pointer storage area P_{B}(12) is associated with free pointer/pointer storage area P_{FP}(12). Host index number N_{H13} and FM index number N_{B1-3} are associated with buffer pointer storage area P_{B}(13). Buffer pointer storage area P_{B}(13) is associated with free pointer/pointer storage area P_{FP}(13). Host index number N_{H14} and FM index number N_{B2-3} are associated with buffer pointer storage area P_{B}(14). Buffer pointer storage area P_{B}(14) is associated with free pointer/pointer storage area P_{FP}(14). Host index number N_{H15} and FM index number N_{B3-3} are associated with buffer pointer storage area P_{B}(15). Buffer pointer storage area P_{B}(15) is associated with free pointer/pointer storage area P_{FP}(15).

The host buffer controller 302 refers to a buffer pointer storage area P_{B}(A) (A=0 to 15) associated with a host index number indicated by the write pointer P_{W}, and obtains a data buffer number stored in the buffer pointer storage area P_{B}(A). The host buffer controller 302 writes write data to a data buffer area corresponding to the obtained data buffer number.

Each bank N controller (N=0, 1, 2, or 3) in the FM buffer controller 303 refers to a buffer pointer storage area P_{B}(C) (C=0 to 15) associated with an FM index number N_{BN-M} (M=0, 1, 2, or 3) indicated by the read pointer P_{R}, and reads a data buffer number stored in the buffer pointer storage area P_{B}(C). The bank N controller (N=0, 1, 2, or 3) reads data from a data buffer area corresponding to the data buffer number, and writes the read data in a corresponding bank of the NAND flash memory. After that, the bank N controller (N=0, 1, 2, or 3) registers the data buffer number in a location indicated by the data buffer registration start pointer P_{T} for the buffer pointer, in order to use the used data buffer for the next transfer. At the same time, the used buffer pointer is changed to “free”.

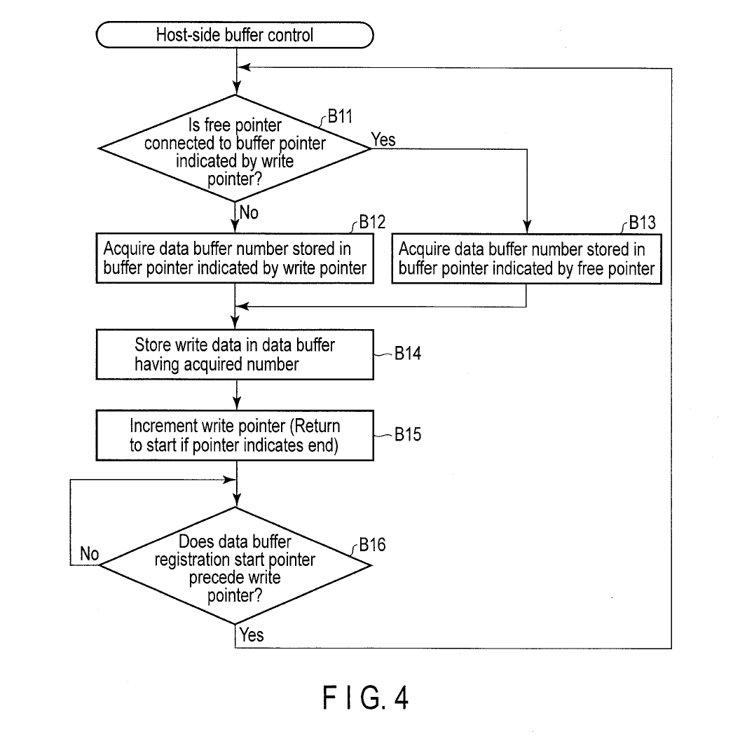

FIG. 4 is a flowchart for explaining the operation of the host buffer controller 302 in a write process.

The host buffer controller 302 determines whether a free pointer/pointer is stored in a free pointer/pointer storage area associated with a buffer pointer storage area corresponding to the write pointer (step B11). If it is determined that no free pointer/pointer is stored, the host buffer controller 302 acquires a data buffer number stored in the buffer pointer storage area corresponding to the write pointer (step B12). If it is determined that a free pointer/pointer is stored, the host buffer controller 302 acquires a data buffer number stored in a free pointer storage area indicated by the free pointer/pointer (step B13). The host buffer controller 302 stores write data in a data buffer area corresponding to the acquired data buffer number (step B14). The host buffer controller 302 increments the value of the write pointer by 1, so that the write pointer indicates the next host index number. Note that if the write pointer is 15, the host buffer controller 302 resets the write pointer to zero (step B15). The host buffer controller 302 determines whether the value of the data buffer registration start pointer precedes the value of the write pointer (step B16). If it is determined that the former value does not precede the latter (No in step B16), the host buffer controller 302 periodically performs a process in step B17. If it is determined that the former value precedes the latter (Yes in step B16), the host buffer controller 302 sequentially executes the processes from step B11.

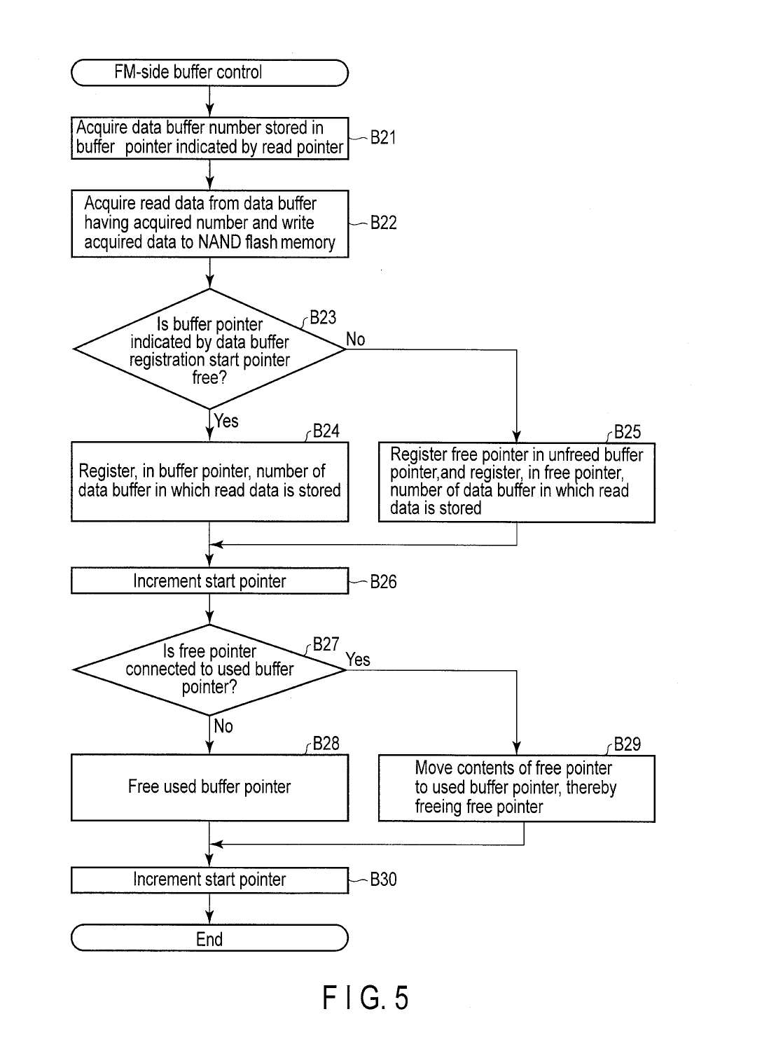

FIG. 5 is a flowchart showing the operation of the bank N controller in a write process.

A bank N controller 303N acquires a data buffer number stored in a buffer pointer storage area corresponding to the read pointer (step B21). The bank N controller 303N acquires data from a data buffer area corresponding to the acquired data buffer number, and writes the acquired data to a corresponding bank N of the NAND flash memory 203 (step B22). The bank N controller 303N determines whether a buffer pointer storage area corresponding to the data buffer registration start pointer is free (step B23). If it is determined that the buffer pointer storage area is free (Yes in step B23), the bank N controller 303N writes, to the buffer pointer storage area, a data buffer number corresponding to the data buffer area in which the data acquired in step B22 is stored (step B24). If it is determined that the buffer pointer storage area is not free (No in step B23), the bank N controller 303N writes a free pointer/pointer to the unfreed buffer pointer storage area, and writes, to the free pointer storage area, the data buffer number corresponding to the data buffer area in which the data acquired in step B22 is stored (step B25). The bank N controller 303N increments the start pointer by 1 (step B26). The bank N controller 303N determines whether a free pointer/pointer is stored in the used buffer pointer storage area (step B27). If it is determined that no free pointer/pointer is stored (No in step B27), the bank N controller 303N frees the used buffer pointer storage area (step B28). If it is determined that a free pointer/pointer is stored (Yes in step B27), the bank N controller 303N moves the data buffer number stored in the free pointer storage area to the used buffer pointer storage area, thereby freeing the free pointer storage area (step B29). The bank N controller 303N then frees the free pointer/pointer storage area. The bank N controller 303N increments the value of the read pointer, so that the value of the new read pointer indicates a corresponding FM index of the next block (step B30). The value of the read pointer is incremented as follows. The bank N controller (N=0, 1, 2, or 3) increments the value of Y of BX-Y (Y=0, 1, 2, or 3) by +1. Note that if the value of Y is 3, the bank X controller (X=0, 1, 2, or 3) resets the value of Y to zero.

Next, an actual write procedure will be explained.

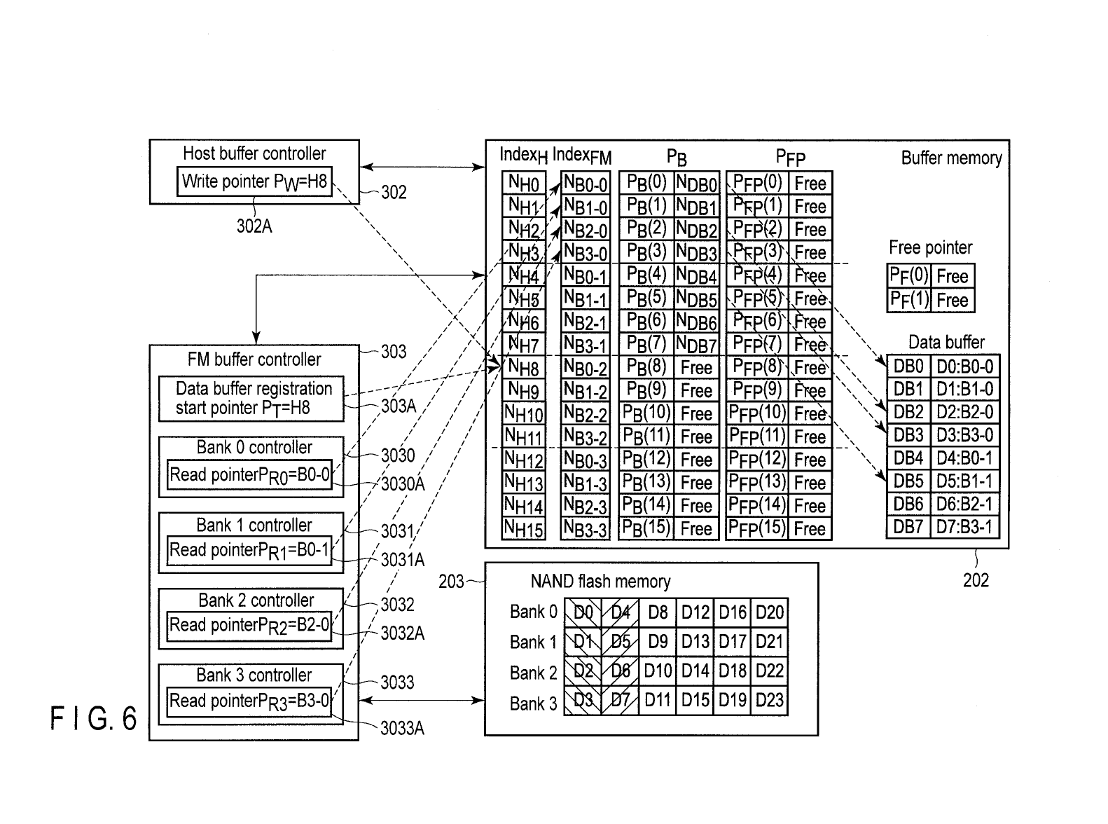

FIG. 6 is a view showing the host buffer controller 302, flash memory buffer controller 303, buffer memory 202, and NAND flash memory 203 in the initial state of writing.

The write pointer P_{W} indicates host index number N_{H8}. The data buffer registration start pointer P_{T}(H8) indicates host index number N_{H8}.

The read pointer P_{R0} indicates FM index number N_{B0-0}. The read pointer P_{R1} indicates FM index number N_{B1-0}. The read pointer P_{R2} indicates FM index number N_{B2-0}. The read pointer P_{R3} indicates FM index number N_{B3-0}.

Data buffer number N_{DB0} is stored in buffer pointer storage area P_{B}(0). Data buffer number N_{DB1} is stored in buffer pointer storage area P_{B}(1). Data buffer number N_{DB2} is stored in buffer pointer storage area P_{B}(2). Data buffer number N_{DB3} is stored in buffer pointer storage area P_{B}(3). Data buffer number N_{DB4} is stored in buffer pointer storage area P_{B}(4). Data buffer number N_{DB5} is stored in buffer pointer storage area P_{B}(5). Data buffer number N_{DB6} is stored in buffer pointer storage area P_{B}(6). Data buffer number N_{DB7} is stored in buffer pointer storage area P_{B}(7). Buffer pointer storage areas P_{B}(8) to P_{B}(15) are free.

Free pointer/pointer storage areas P_{FP}(0) to P_{FP}(15) are free.

Free pointer storage areas P_{F}(0) and P_{F}(1) are free. Data D0 is stored in data buffer area DB0.

Data D1 is stored in data buffer area DB1. Data D2 is stored in data buffer area DB2. Data D3 is stored in data buffer area DB3. Data D4 is stored in data buffer area DB4. Data D5 is stored in data buffer area DB5. Data D6 is stored in data buffer area DB6. Data D7 is stored in data buffer area DB7.

The bank 0 controller 3030 reads data D0 from data buffer area DB0, and writes read data D0 to bank 0 of the NAND flash memory 203. The bank 1 controller 3031 reads data D1 from data buffer area DB1, and writes read data D1 to bank 1 of the NAND flash memory 203. The bank 2 controller 3032 reads data D2 from data buffer area DB2, and writes read data D2 to bank 2 of the NAND flash memory 203. The bank 3 controller 3033 reads data D3 from data buffer area DB3, and writes read data D3 to bank 3 of the NAND flash memory 203.

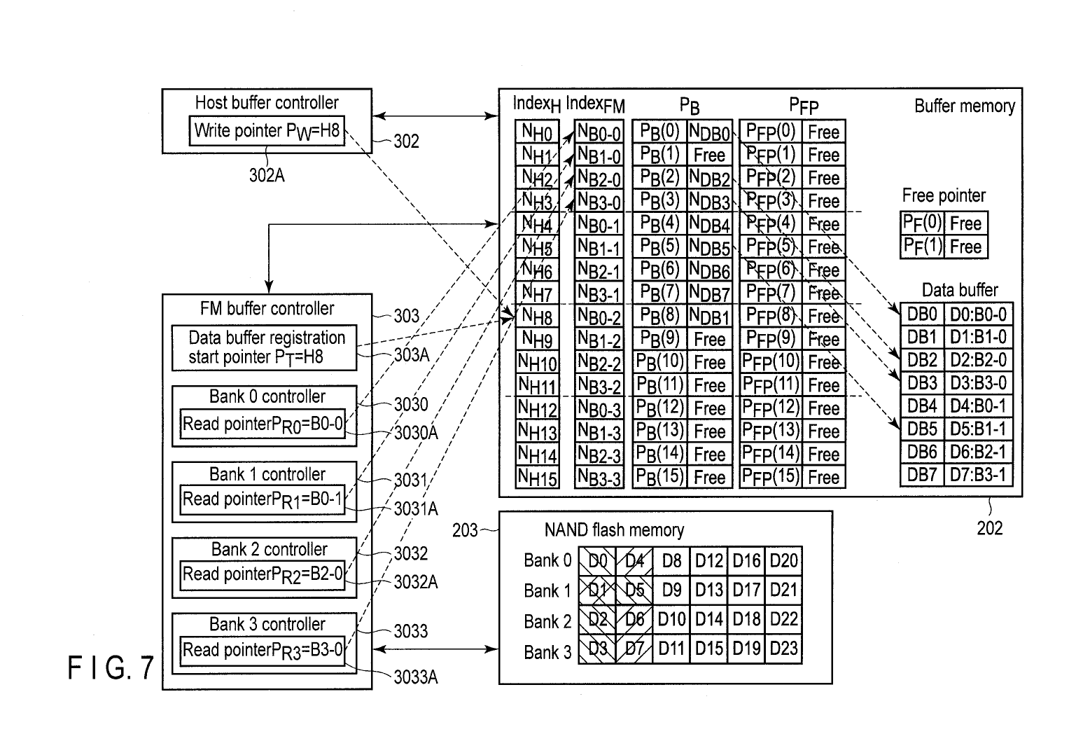

FIGS. 7, 8, 9, and 10 are views for explaining the procedure of processing after data D1 is written to the first block of bank 1.

The bank 1 controller 3031 determines whether buffer pointer storage area P_{B}(8) associated with host index number N_{H8} indicated by the data buffer registration start pointer P_{T}(H8) stored in the memory unit 303A of the FM buffer controller 303 is free.

Since buffer pointer storage area P_{B}(8) is free, as shown in FIG. 7, the bank 1 controller 3031 stores, in buffer pointer storage area P_{B}(8) associated with host index number N_{H8}, data buffer number N_{DB1} indicating data buffer area DB1 in which read data D1 is stored.

The bank 1 controller 3031 determines whether a free pointer/pointer is stored in free pointer/pointer storage area P_{FP}(8) associated with used buffer pointer storage area P_{B}(1). Since no free pointer/pointer is stored, the bank 1 controller frees used buffer pointer storage area P_{B}(1).

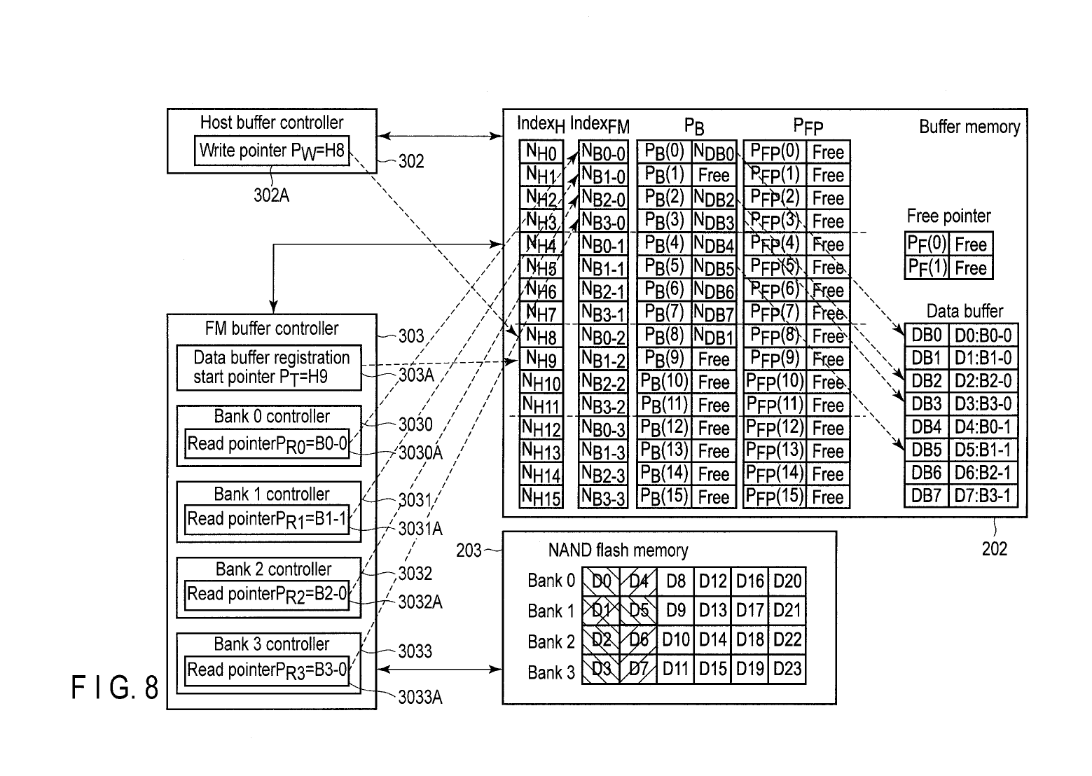

As shown in FIG. 8, the bank 1 controller 3031 sets the data buffer registration start pointer P_{T} to H9 by incrementing the value of the data buffer registration start pointer P_{T} by 1. The bank 1 controller 3031 sets the read pointer P_{R1} to B1-1 by incrementing the value of the read pointer P_{R1} by 1.

The bank 1 controller 3031 reads data buffer number N_{DB5} from buffer pointer storage area P_{B}(5) associated with a flash memory index number indicated by B1-1 as the value of the read pointer P_{R1}. The bank 1 controller 3031 reads data from data buffer area DB2 indicated by data buffer number N_{DB5}. The bank 1 controller 3031 starts writing the read data to the second block of bank 1.

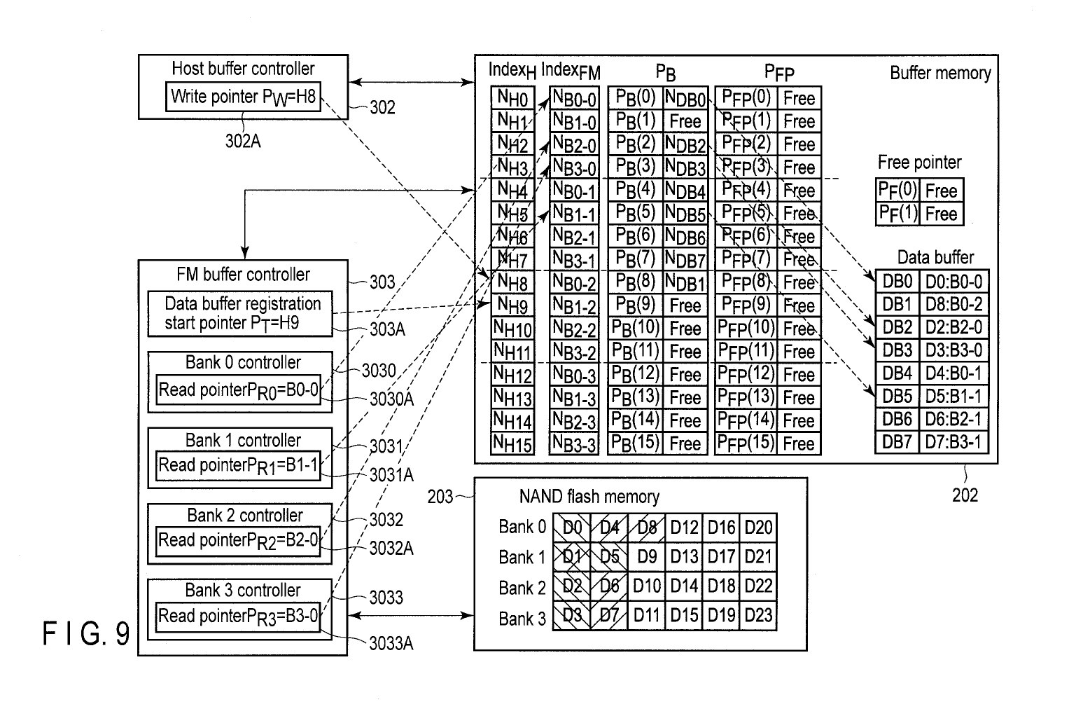

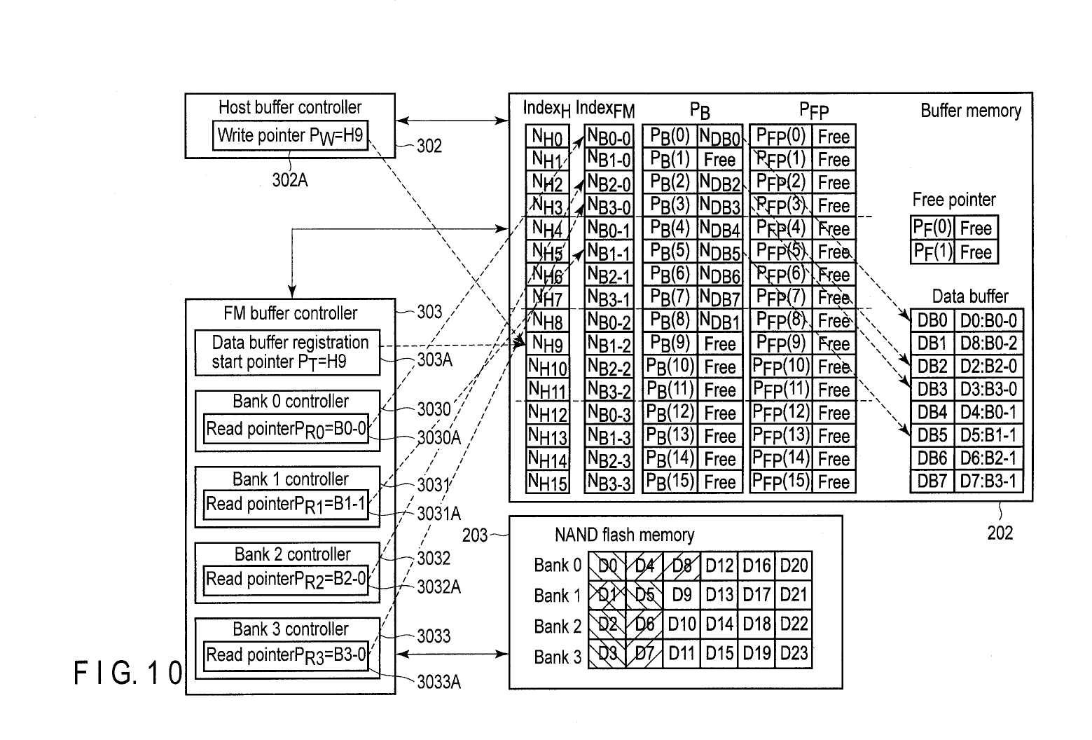

The host buffer controller 302 determines whether a free pointer/pointer is stored in free pointer/pointer storage area P_{PF}(8) associated with buffer pointer storage area P_{B}(8) associated with host index number N_{H8} indicated by the write pointer P_{W}(H8). Since no free pointer/pointer is stored, the host buffer controller 302 acquires data buffer number N_{DB1} in buffer pointer storage area P_{B}(8) associated with host index number N_{H8} indicated by the write pointer P_{W}(H8). As shown in FIG. 9, the host buffer controller 302 stores data D8 in data buffer area DB1 indicated by data buffer number N_{DB1}. As shown in FIG. 10, the host buffer controller sets the write pointer P_{W} to 9 by incrementing the value of the write pointer P_{W}.

The host buffer controller 302 determines whether the value of the data buffer registration start pointer P_{T} precedes the value of the write pointer P_{W}. Since the value of the data buffer registration start pointer P_{T} does not precede the value of the write pointer P_{W}, the host buffer controller 302 periodically determines whether the value of the data buffer registration start pointer P_{T} precedes the value of the write pointer P_{W}.

Subsequently, data D3 is written to the first block of bank 3, data D2 is written to the first block of bank 2, data D5 is written to the second block of bank 1, data D7 is written to the second block of bank 3, data D9 is written to the third block of bank 1, data D6 is written to the second block of bank 2, and data D11 is written to the third block of bank 3 in this order. An explanation of processing after data D3, D2, D5, D7, D9, and D6 are written will be omitted.

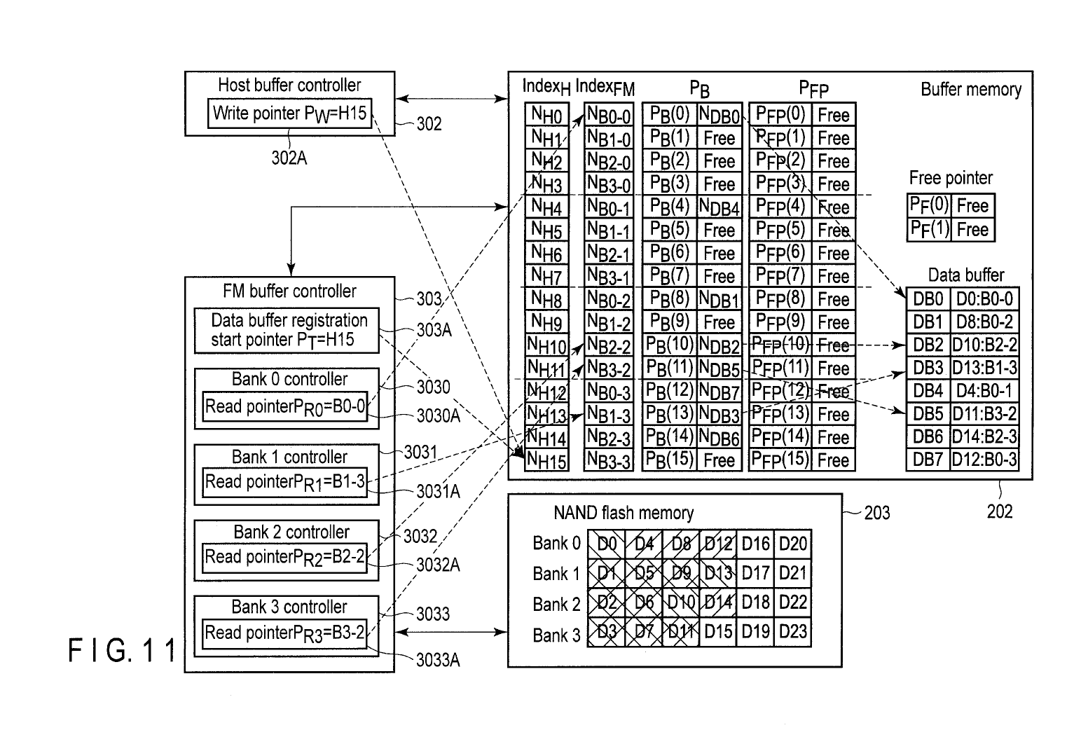

FIG. 11 is a view showing a state after data D11 is written to the third block of bank 3. As shown in FIG. 11, the write pointer P_{W} is H15. The data buffer registration start pointer P_{T} is H15. The read pointer P_{R0} is B0-0. The read pointer P_{R1} is B1-3. The read pointer P_{R2} is B2-2. The read pointer P_{R3} is B3-2.

Data buffer number N_{DB0} is stored in buffer pointer storage area P_{B}(0). Data buffer number N_{DB4} is stored in buffer pointer storage area P_{B}(4). Data buffer number N_{DB1} is stored in buffer pointer storage area P_{B}(8). Data buffer number N_{DB2} is stored in buffer pointer storage area P_{B}(10). Data buffer number N_{DB5} is stored in buffer pointer storage area P_{B}(11). Data buffer number N_{DB7} is stored in buffer pointer storage area P_{B}(12). Data buffer number N_{DB3} is stored in buffer pointer storage area P_{B}(13). Data buffer number N_{DB6} is stored in buffer pointer storage area P_{B}(14).

Buffer pointer storage areas P_{B}(1), P_{B}(2), P_{B}(3), P_{B}(5), P_{B}(6), P_{B}(7), P_{B}(9), and P_{B} (15) are free.

Free pointer/pointer storage areas P_{FP}(0) to P_{FP}(15) are free. Free pointer storage areas P_{F}(0) and P_{F}(1) are free.

Data D0 is stored in data buffer area DB0. Data D8 is stored in data buffer area DB1. Data D10 is stored in data buffer area DB2. Data D13 is stored in data buffer area DB3. Data D4 is stored in data buffer area DB4. Data D11 is stored in data buffer area DB5. Data D14 is stored in data buffer area DB6. Data D12 is stored in data buffer area DB7.

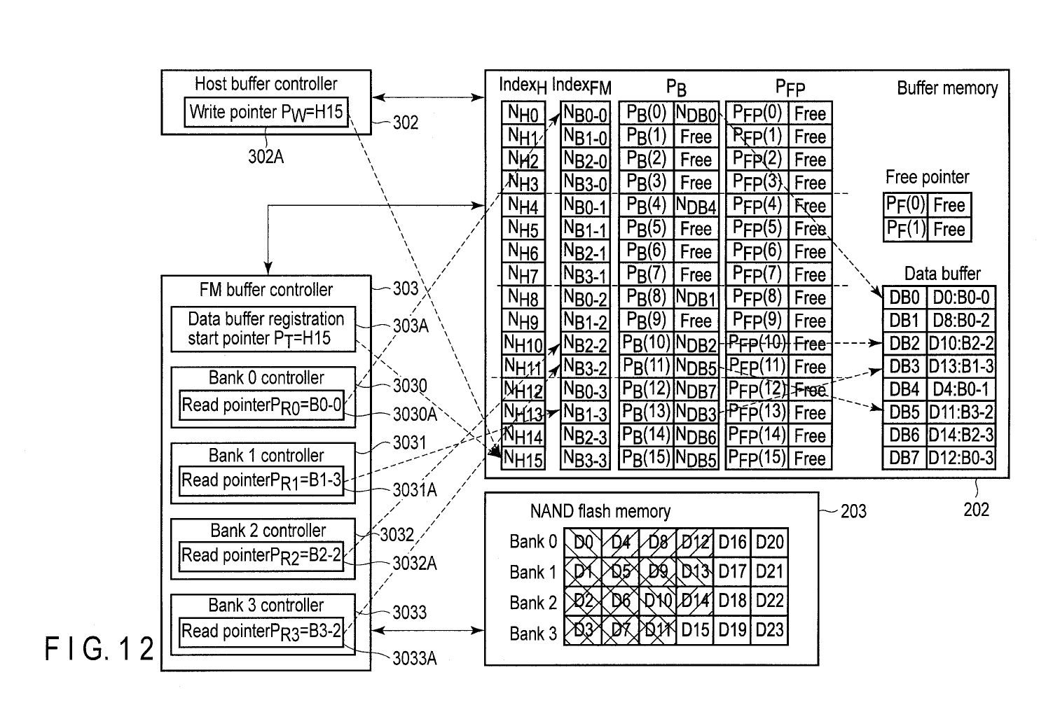

FIGS. 12, 13, 14, 15, and 16 are views for explaining the procedure of processing after data D11 is written to the third block of bank 3.

The bank 3 controller 3033 determines whether buffer pointer storage area P_{B}(15) associated with host index number N_{H15} indicated by the data buffer registration start pointer P_{T}(H15) stored in the memory unit 303A of the FM buffer controller 303 is free. Since buffer pointer storage area P_{B}(15) is free, as shown in FIG. 12, the bank 3 controller 3033 stores, in buffer pointer P_{B}(15) associated with host index number N_{H15}, data buffer number N_{DB5} indicating data buffer area DB5 in which read data D11 is stored.

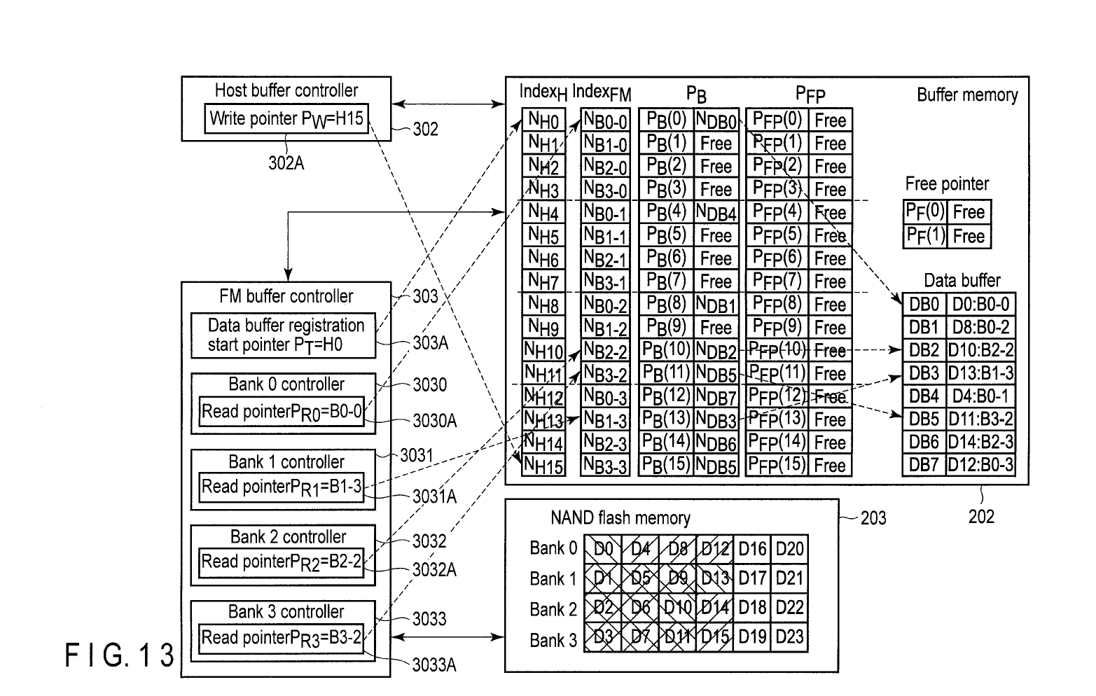

As shown in FIG. 13, the bank 3 controller 3033 sets the data buffer registration start pointer P_{T} to H0 by incrementing the value of the data buffer registration start pointer P_{T}.

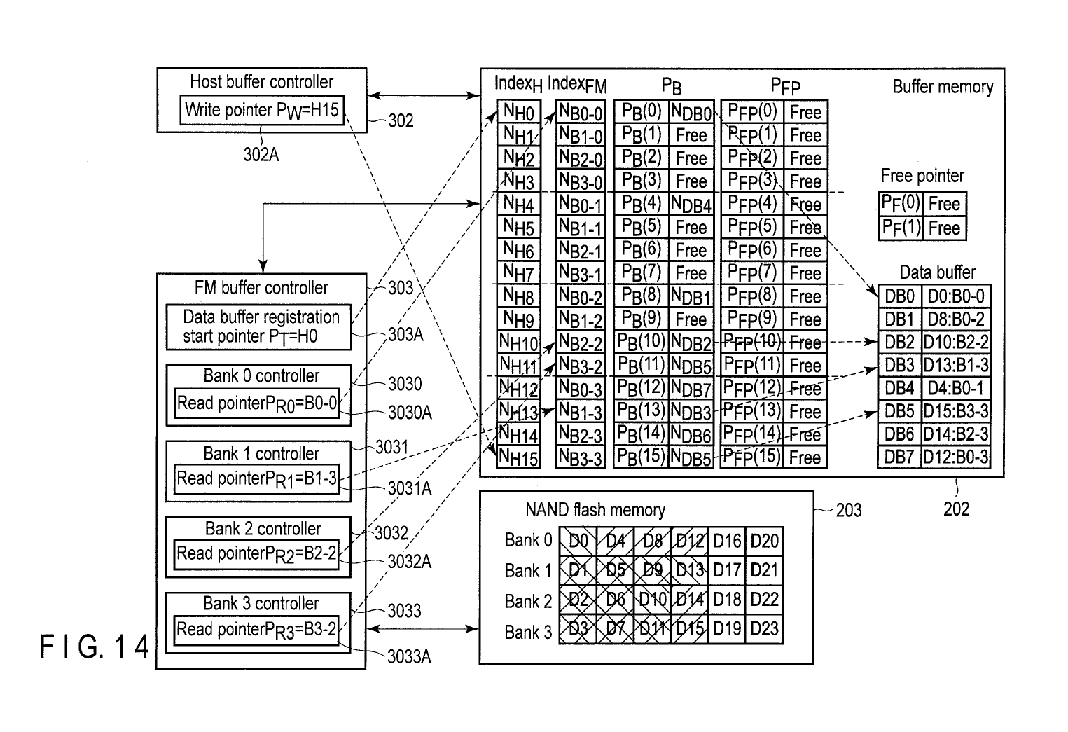

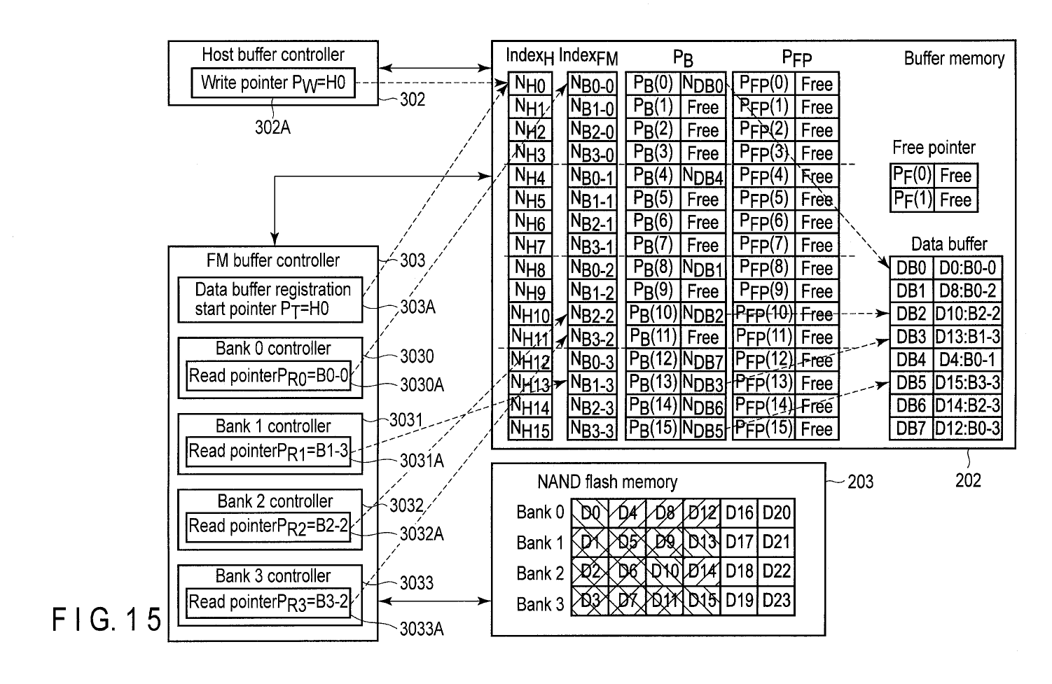

Since the data buffer registration start pointer P_{T} indicates the write pointer P_{W}, the host buffer controller 302 determines whether a free pointer/pointer is stored in free pointer/pointer storage area P_{FP}(15) associated with buffer pointer storage area P_{B}(15) associated with host index number N_{H15} indicated by the write pointer P_{W}(H15). Since no free pointer/pointer is stored, the host buffer controller 302 acquires data buffer number N_{DB5} in buffer pointer P_{B}(15) associated with host index number N_{H15} indicated by the write pointer P_{W}(H15). As shown in FIG. 14, the host buffer controller 302 stores data D15 in data buffer area DB5 indicated by data buffer number N_{DB5}. As shown in FIG. 15, the host buffer controller sets the write pointer P_{W} to zero by incrementing the value of the write pointer P_{W}.

The bank 3 controller 3033 determines whether a free pointer/pointer is stored in free pointer/pointer storage area P_{FP}(11) associated with used buffer pointer storage area P_{B}(11). Since no free pointer/pointer is stored, the bank 3 controller 3033 frees used buffer pointer storage area P_{B}(11).

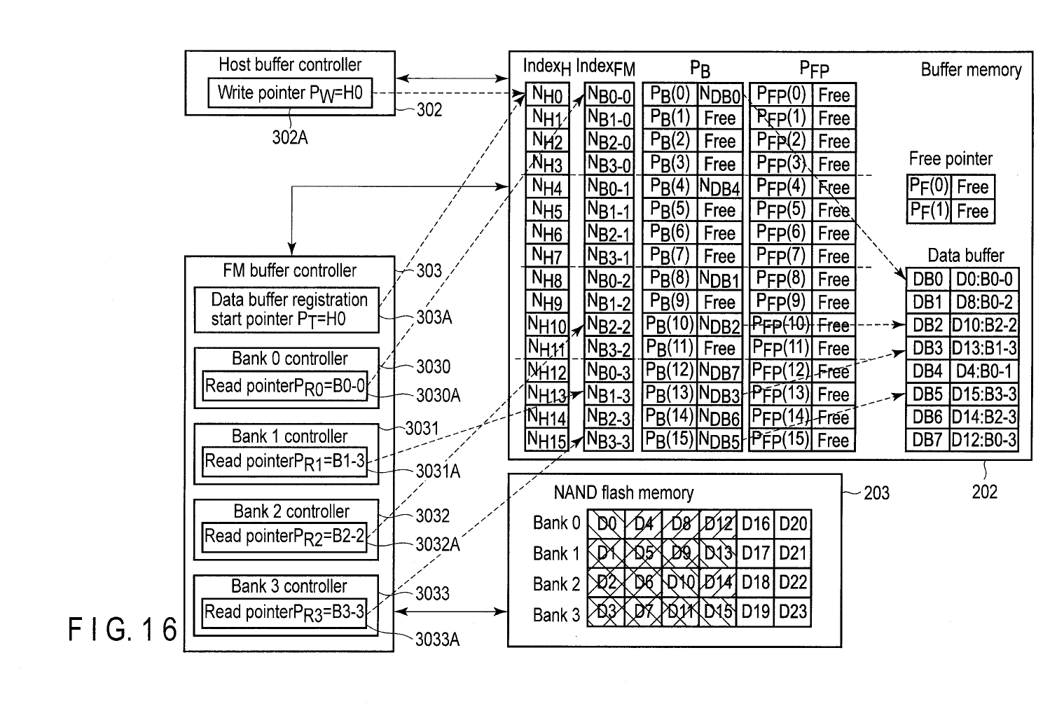

As shown in FIG. 16, the bank 3 controller 3033 sets the read pointer P_{R3} to B3-3 by incrementing the value of the read pointer P_{R3}. The bank 3 controller 3033 reads data buffer number N_{DB5} from buffer pointer P_{B}(15) associated with a flash memory index indicated by B3-3 as the value of the read pointer P_{R3}. The bank 3 controller 3033 then reads data D15 from data buffer area DB5 indicated by data buffer number N_{DB5}, and writes read data D15 to the third block of bank 3.

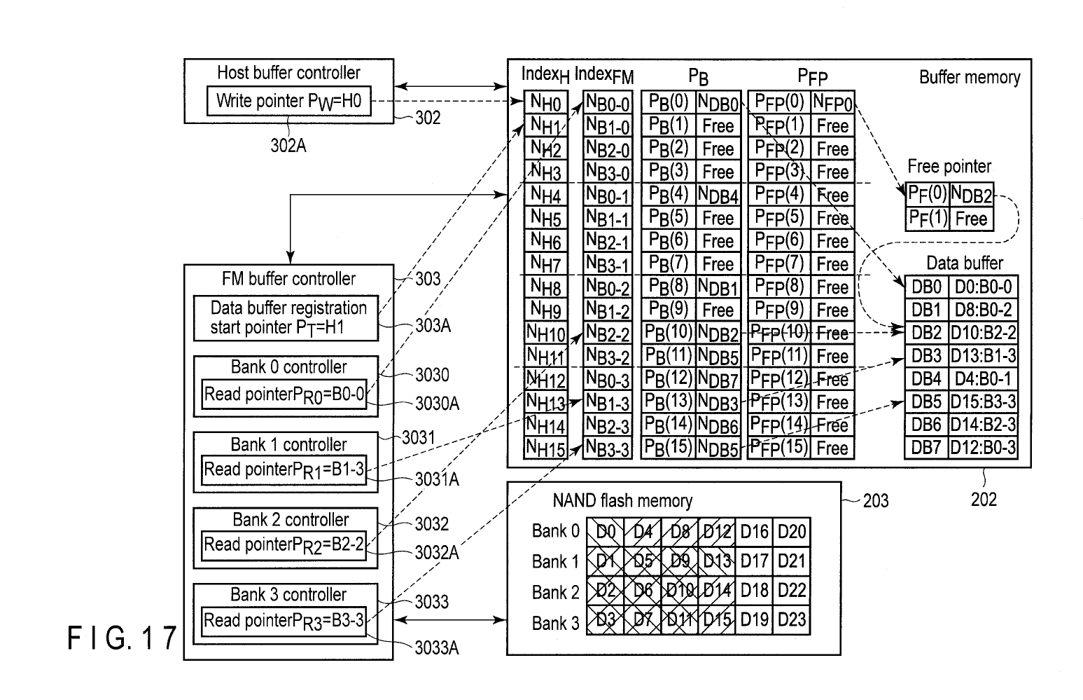

FIGS. 17, 18, 19, 20, and 21 are views for explaining the procedure of processing after data D10 is written to the third block of bank 2.

The bank 2 controller 3032 determines whether buffer pointer storage area P_{B}(0) associated with host index number N_{H0} indicated by the data buffer registration start pointer P_{T}(H0) stored in the storage unit 303A of the FM buffer controller 303 is free. Since buffer pointer P_{B}(0) is not free, as shown in FIG. 17, the bank 2 controller 3032 stores free pointer P_{F}(0) in free pointer/pointer storage area P_{FP}(0) associated with buffer pointer storage area P_{B}(0). The bank 2 controller 3032 stores, in free pointer P_{F}(0), data buffer number N_{DB2} indicating data buffer area DB10 in which read data D10 is stored.

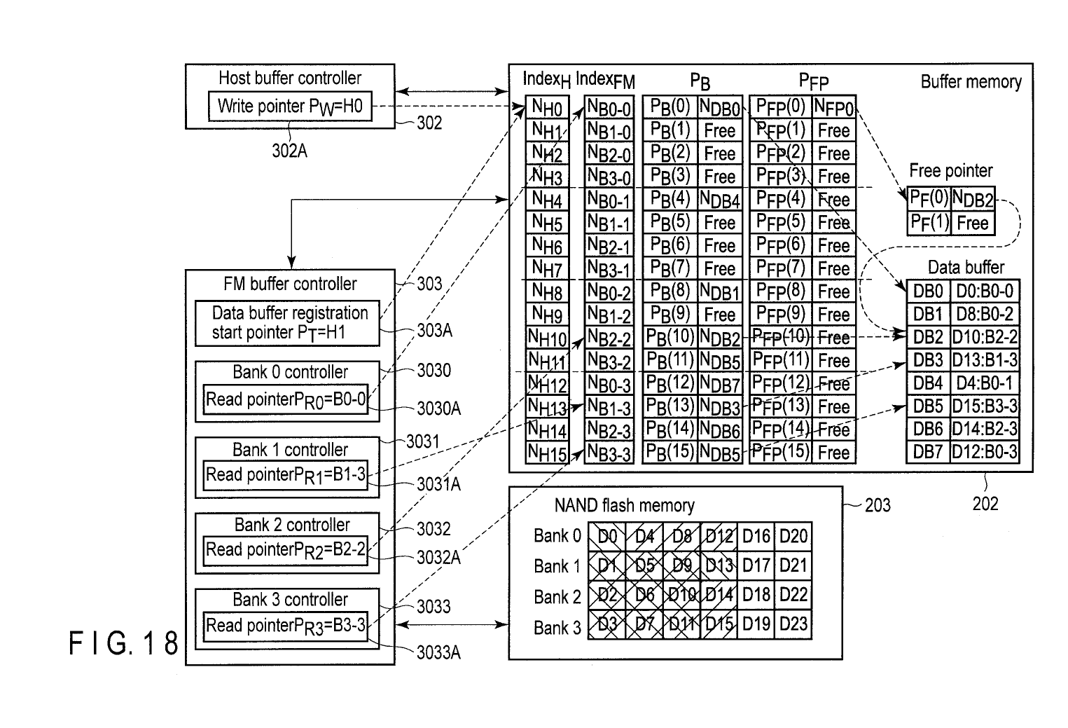

As shown in FIG. 18, the bank 2 controller 3032 sets the data buffer registration start pointer P_{T} to H1 by incrementing the value of the data buffer registration start pointer P_{T}.

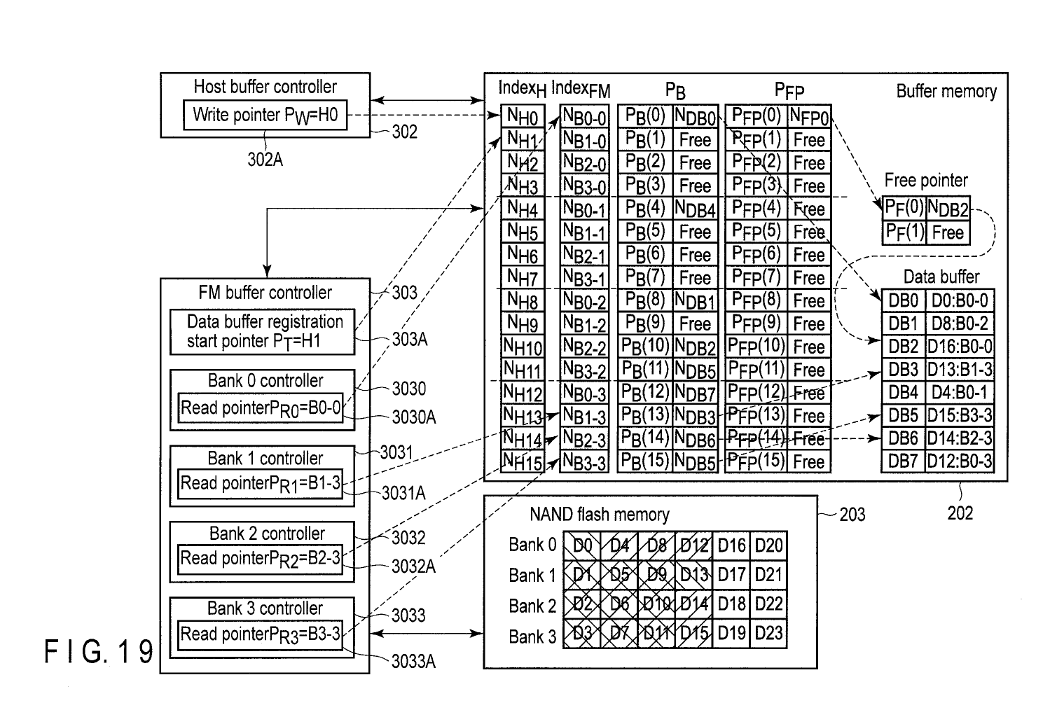

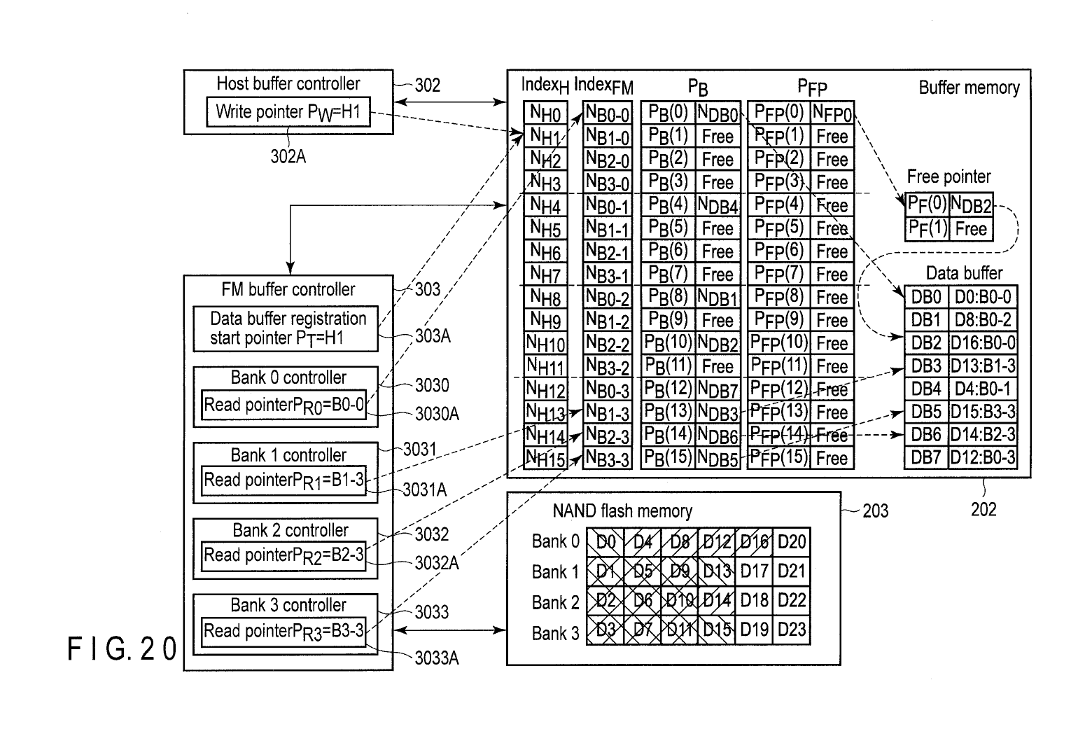

Since the data buffer registration start pointer P_{T} precedes the write pointer P_{W}, the host buffer controller 302 determines whether a free pointer/pointer is stored in free pointer/pointer storage area P_{FP}(0) associated with buffer pointer storage area P_{B}(0) associated with host index number N_{H0} indicated by the write pointer P_{W}(H0). Since a free pointer/pointer is stored, the host buffer controller 302 acquires data buffer number N_{DB2} in free pointer P_{F}(0) indicated by the free pointer/pointer stored in free pointer/pointer storage area P_{FP}(0). As shown in FIG. 19, the host buffer controller 302 stores data D16 in data buffer area DB2 indicated by data buffer number N_{DB2}. As shown in FIG. 20, the host buffer controller sets the write pointer P_{W} to H1 by incrementing the value of the write pointer P_{W} by 1.

The bank 2 controller 3032 determines whether a free pointer/pointer is stored in free pointer/pointer storage area P_{FP}(0) associated with used buffer pointer storage area P_{B}(0). Since no free pointer/pointer is stored, the bank 2 controller 3032 frees used buffer pointer storage area P_{B}(0).

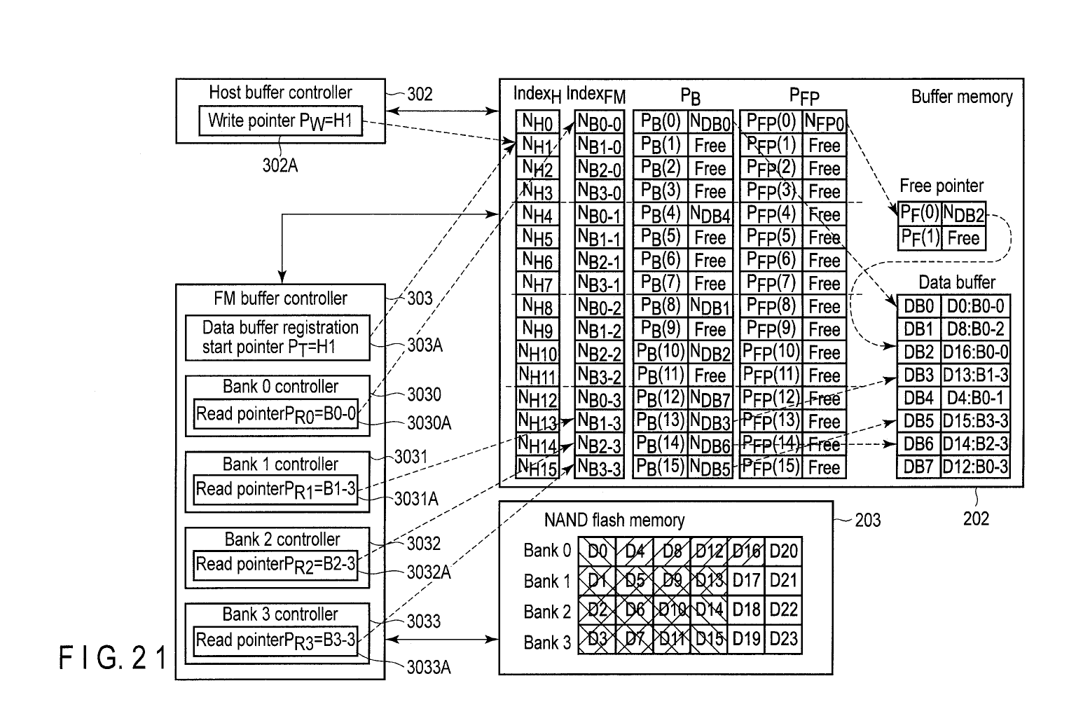

As shown in FIG. 21, the bank 2 controller 3032 sets the read pointer P_{R2} to B2-3 by incrementing the value of the read pointer P_{R2} by 1. The bank 2 controller 3032 reads data buffer number N_{DB6} from buffer pointer P_{B}(14) associated with a flash memory index indicated by B2-3 as the value of the read pointer P_{R2}. The bank 2 controller 3032 reads data D14 from data buffer area DB6 indicated by data buffer number N_{DB6}, and writes read data D14 to the third block of bank 2.

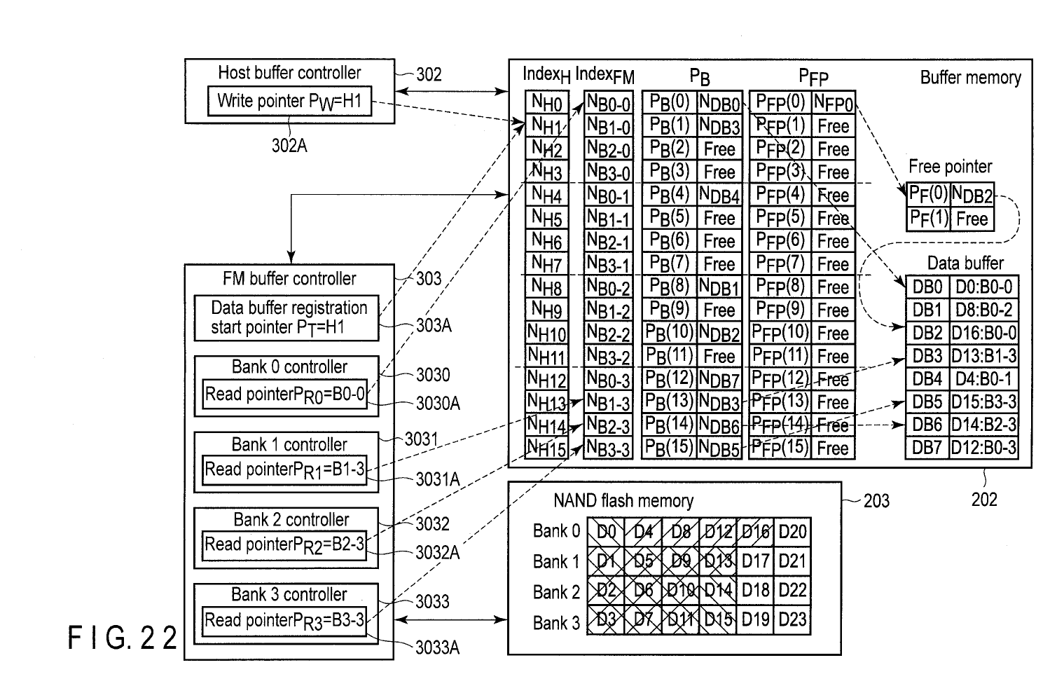

FIGS. 22, 23, 24, 25, and 26 are views for explaining the procedure of processing after data D13 is written to the fourth block of bank 1.

The bank 1 controller 3031 determines whether buffer pointer storage area P_{B}(1) associated with host index number N_{H1} indicated by the data buffer registration start pointer P_{T}(H1) stored in the storage unit 303A of the FM buffer controller 303 is free. Since buffer pointer storage area P_{B}(1) is free, as shown in FIG. 22, the bank 1 controller 3031 stores, in buffer pointer P_{B}(1) associated with host index number N_{H1}, data buffer number N_{DB3} indicating data buffer area DB13 in which read data D13 is stored.

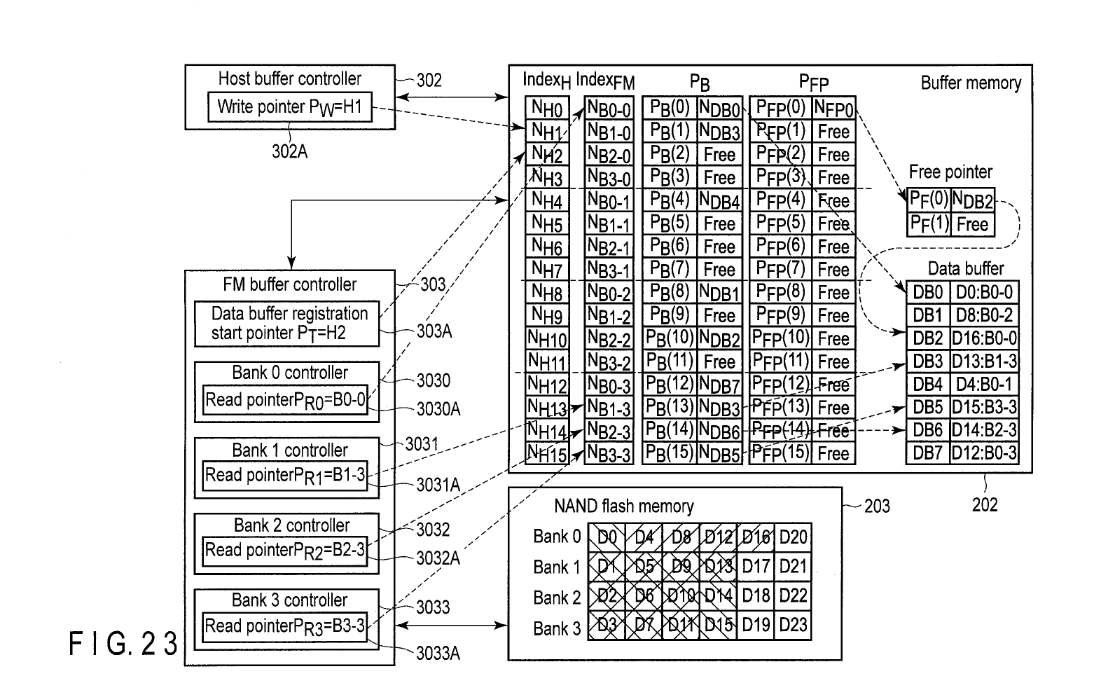

As shown in FIG. 23, the bank 1 controller 3031 sets the data buffer registration start pointer P_{T} to H2 by incrementing the value of the data buffer registration start pointer P_{T} by 1.

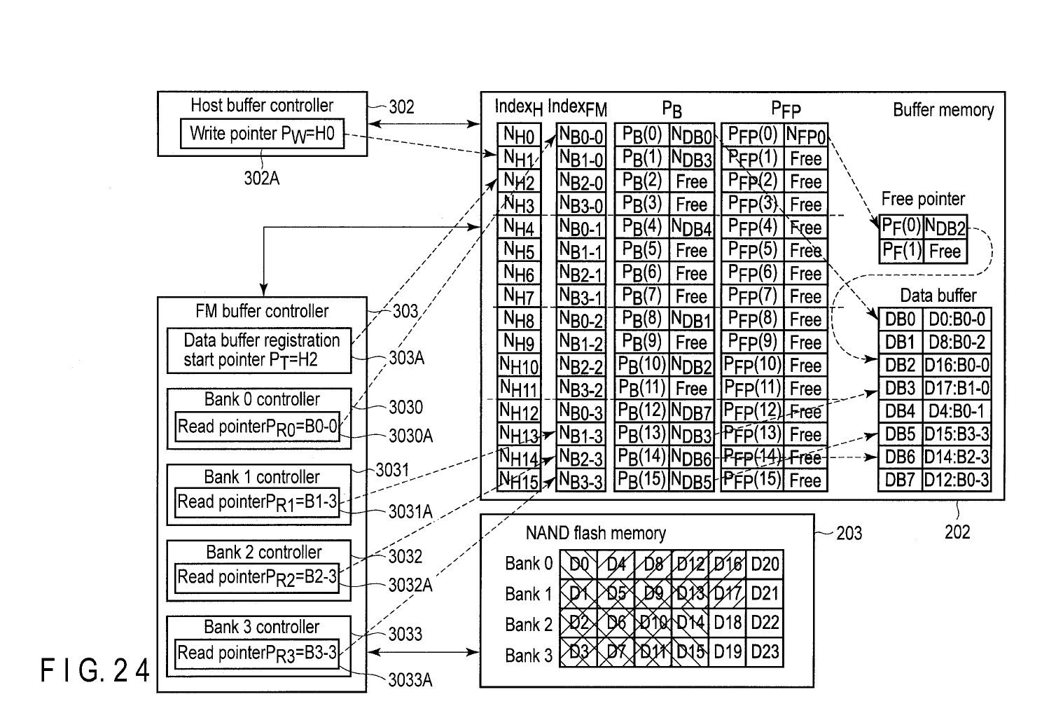

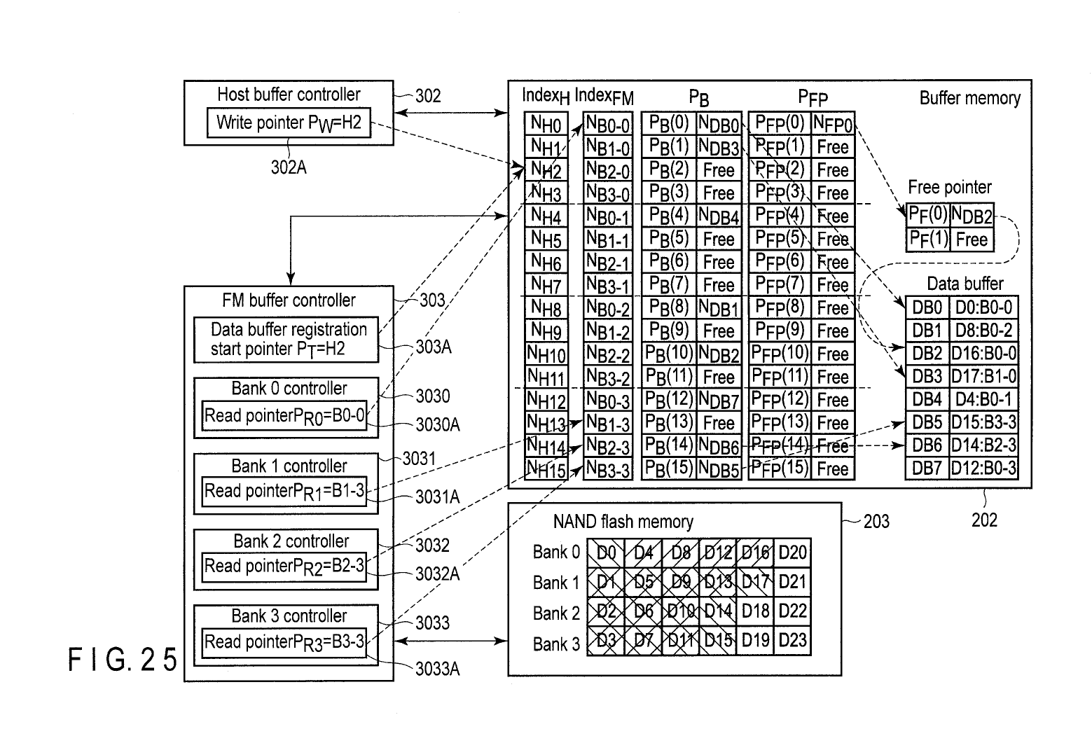

Since the data buffer registration start pointer P_{T} precedes the write pointer P_{W}, the host buffer controller 302 determines whether a free pointer/pointer is stored in free pointer/pointer storage area P_{FP}(1) associated with buffer pointer P_{B}(1) associated with host index number N_{H1} indicated by the write pointer P_{W}(H1). Since no free pointer/pointer is stored, the host buffer controller 302 acquires data buffer number N_{DB3} in buffer pointer storage area P_{B}(1) associated with host index number N_{H1} indicated by the write pointer P_{W}(H1). As shown in FIG. 24, the host buffer controller 302 stores data D17 in data buffer area DB3 indicated by data buffer number N_{DB3}. As shown in FIG. 25, the host buffer controller 302 sets the write pointer P_{W} to H2 by incrementing the value of the write pointer P_{W} by 1.

The bank 1 controller 3031 determines whether a free pointer/pointer is stored in free pointer/pointer storage area P_{FP}(13) associated with used buffer pointer storage area P_{B}(13). Since no free pointer/pointer is stored, the bank 1 controller 3031 frees used buffer pointer P_{B}(13).

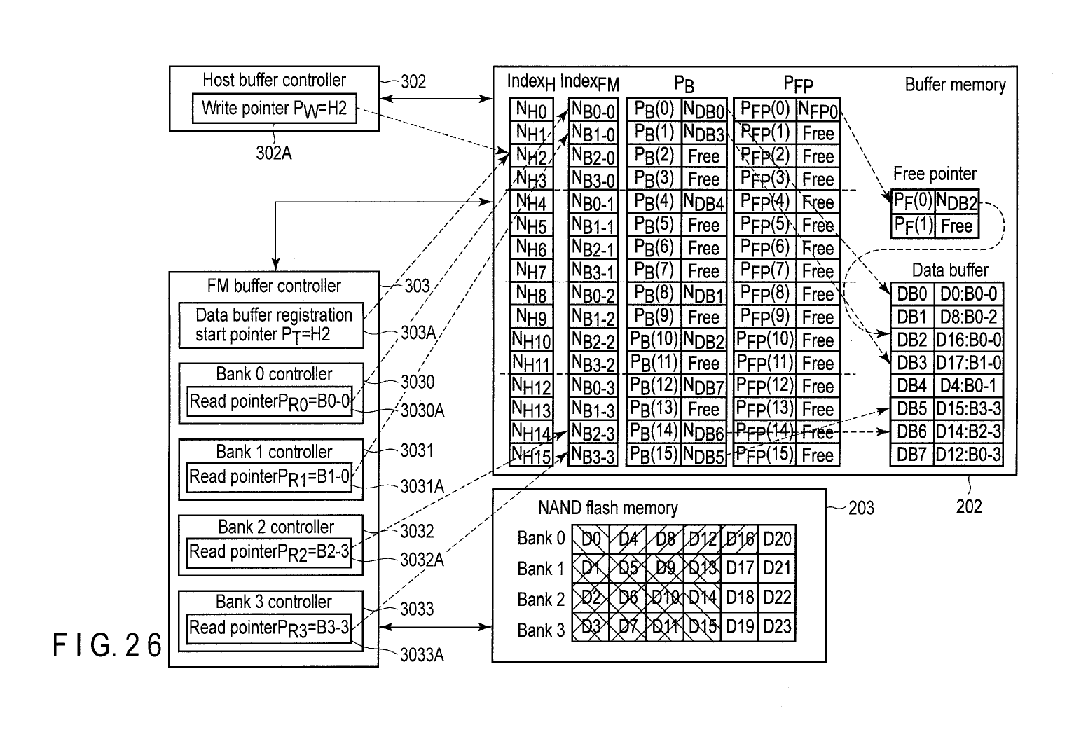

As shown in FIG. 26, the bank 1 controller 3031 sets the read pointer P_{R1} to B1-0 by incrementing the value of the read pointer P_{R1}. The bank 1 controller 3031 reads data buffer number N_{DB3} from buffer pointer P_{B}(1) associated with FM index number N_{B1-0} indicated by the read pointer P_{R1}(B1-0). The bank 1 controller 3031 reads data D17 from data buffer area DB3 indicated by data buffer number N_{DB3}, and writes read data D17 to the fifth block of bank 1.

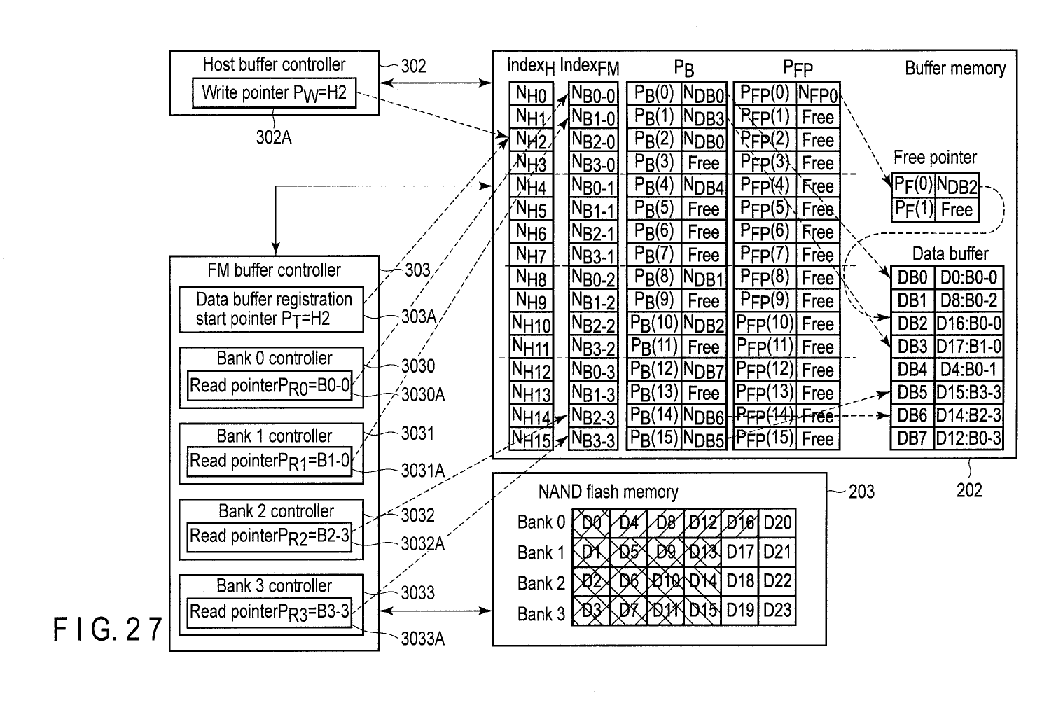

FIGS. 27, 28, 29, 30, 31, and 32 are views for explaining the procedure of processing after data D0 is written to the first block of bank 0.

The bank 0 controller 3030 determines whether a buffer pointer associated with host index number N_{H2} indicated by the data buffer registration start pointer P_{T}(H2) stored in the storage unit 303A of the FM buffer controller 303 is free. Since the buffer pointer is free, as shown in FIG. 27, the bank 0 controller 3030 stores, in buffer pointer P_{B}(2) associated with host index number N_{H2}, data buffer number N_{DB0} indicating data buffer area DB0 in which read data D0 is stored.

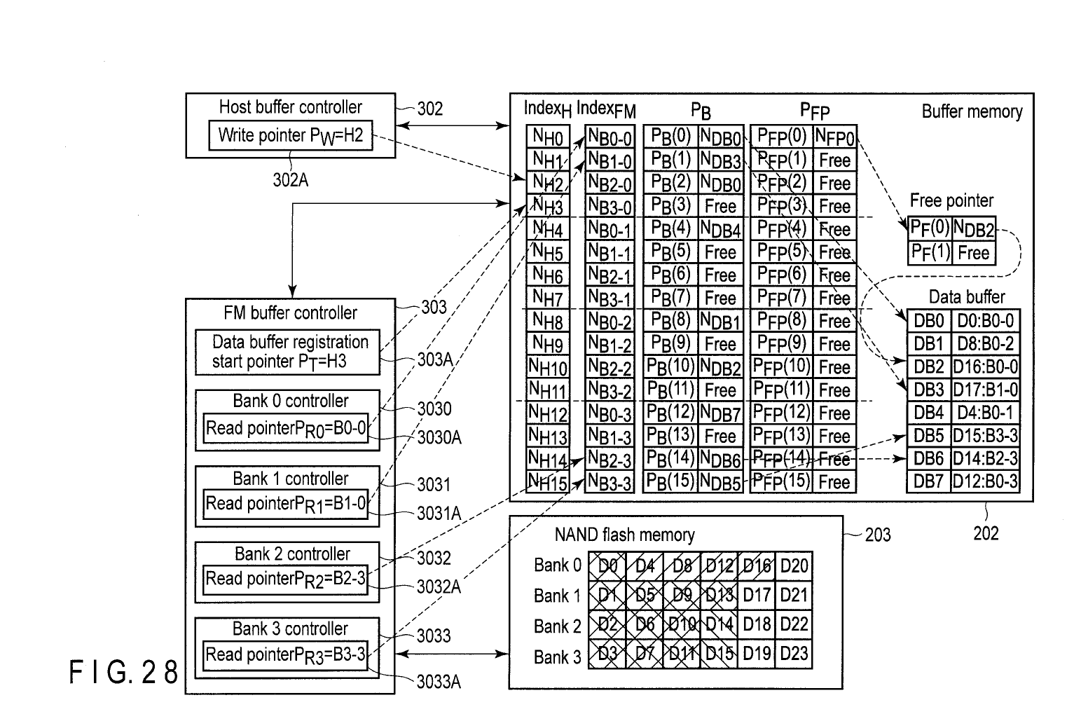

As shown in FIG. 28, the bank 0 controller 3030 sets the data buffer registration start pointer P_{T} to H3 by incrementing the value of the data buffer registration start pointer P_{T}.

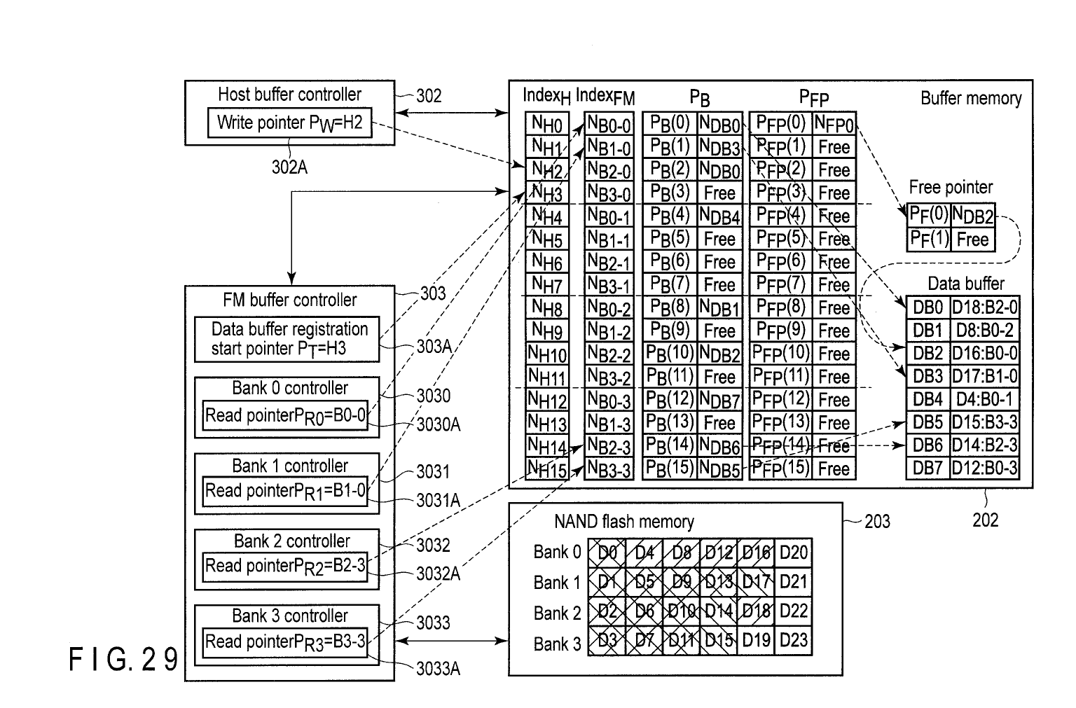

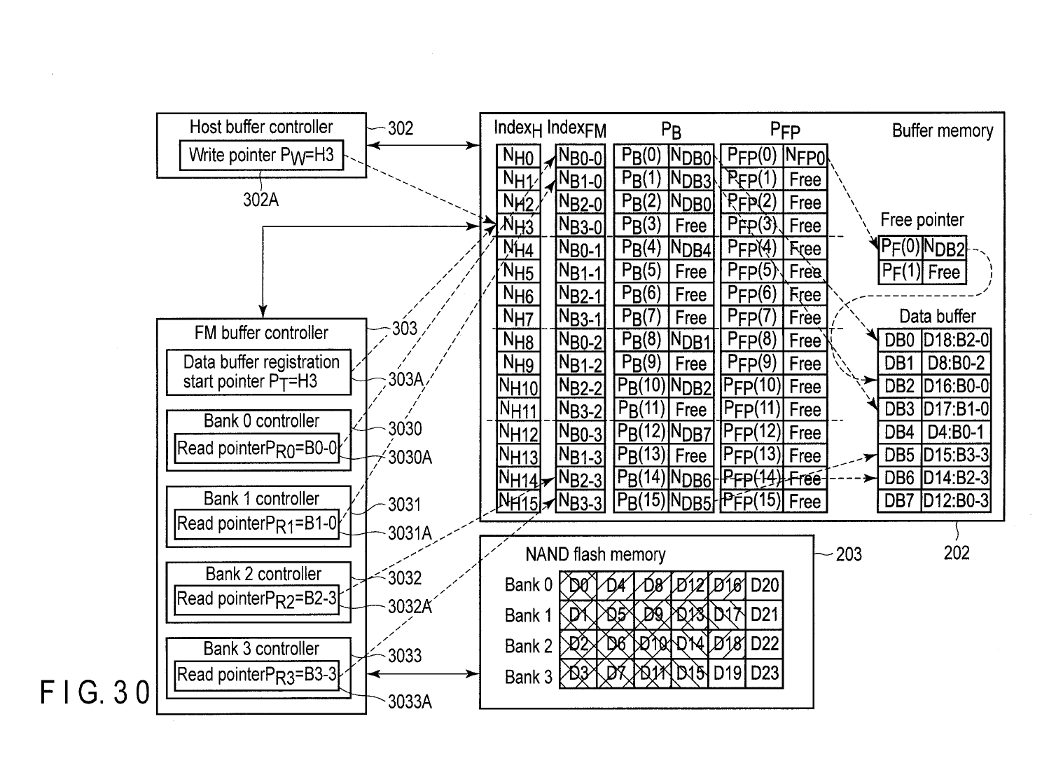

Since the data buffer registration start pointer P_{T} precedes the write pointer P_{W}, the host buffer controller determines whether a free pointer/pointer is stored in free pointer/pointer storage area P_{FP}(2) associated with buffer pointer storage area P_{B}(2) associated with host index number N_{H2} indicated by the write pointer P_{W}(H2). Since no free pointer/pointer is stored, the host buffer controller 302 acquires data buffer number N_{DB0} in buffer pointer storage area P_{B}(2) associated with host index number N_{H1} indicated by the write pointer P_{W}(H1). As shown in FIG. 29, the host buffer controller stores data D18 in data buffer area DB3 indicated by data buffer number N_{DB0}. As shown in FIG. 30, the host buffer controller sets the write pointer P_{W} to H3 by incrementing the value of the write pointer P_{W}.

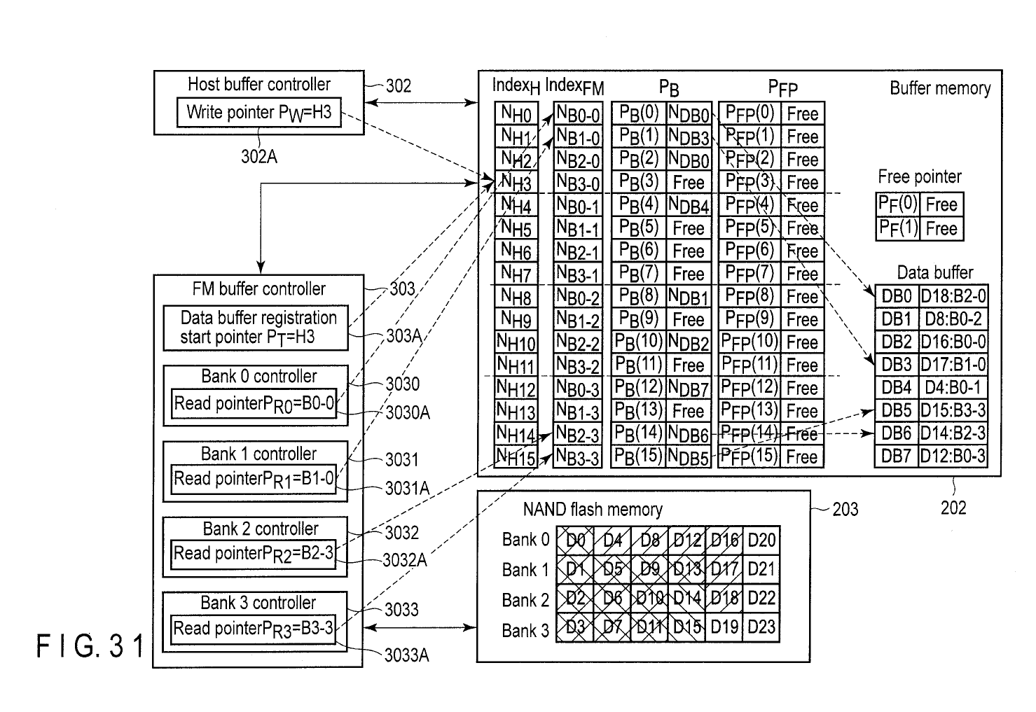

The bank 0 controller 3030 determines whether a free pointer/pointer is stored in free pointer/pointer storage area P_{FP}(0) associated with used buffer pointer storage area P_{B}(0). Since free pointer/pointer P_{FP}(0) is stored, as shown in FIG. 31, the bank 0 controller 3030 moves data buffer number N_{D16} stored in free pointer storage area P_{F}(0) to buffer pointer storage area P_{B}(0), and frees free pointer/pointer storage area P_{FP}(0).

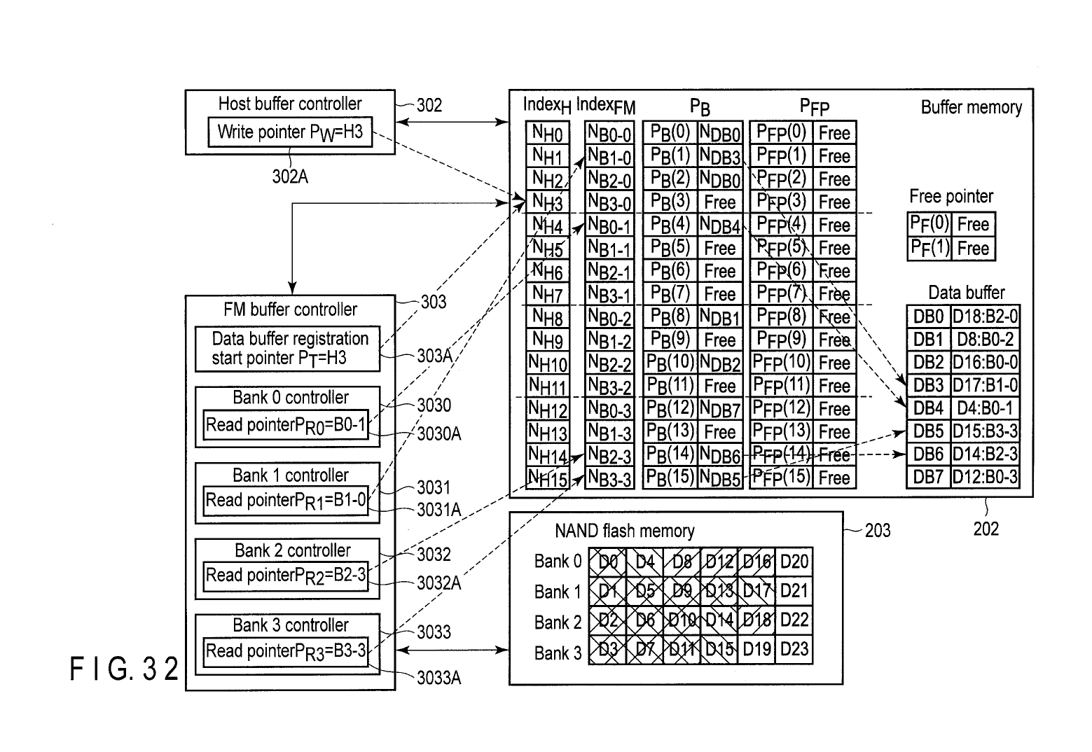

As shown in FIG. 32, the bank 0 controller 3030 sets the read pointer P_{R0} to B0-1 by incrementing the value of the read pointer P_{R0}. The bank 0 controller 3030 reads data buffer number N_{DB4} from buffer pointer P_{B}(4) associated with a flash memory index indicated by B0-1 as the value of the read pointer P_{R0}. The bank 0 controller 3030 reads data D4 from data buffer area DB4 indicated by data buffer number N_{DB4}, and writes read data D4 in the second block of bank 0.

The bank 0 controller 3030, bank 1 controller 3031, bank 2 controller 3032, and bank 3 controller 3033 independently operate for their respective banks, so a preceding controller and succeeding controller exist. As described above, a data buffer number used by a preceding controller is stored in a buffer pointer storage area for the next transfer. Consequently, the preceding controller can advance processing without waiting for a succeeding controller, thereby making effective use of the buffer memory and efficient write control possible. Although a fast controller and slow controller exist in the transfer of one given unit, repetitive transfer averages the speed differences between controllers. When compared to an operation in which a slow controller determines the operation speed, therefore, the operation can be completed within a short time period.

If there is no free pointer, a slow controller makes other controllers impossible to advance further. Although there is a method of enlarging the data buffer in order to prevent this, it is necessary to add buffers equal in number to all banks. When a free pointer is prepared, however, only a succeeding bank can use a free bank, so the efficiency increases.

In the above-mentioned embodiment, the memory device is implemented as an H-HDD. However, the memory device may also be implemented as a solid-state drive (SSD).

Although data is written to the NAND flash memory 203, it is also possible to achieve read access by reversing the direction.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a buffer memory in which data buffer areas are set;
a first write controller configured to sequentially write data transmitted from a host to the data buffer areas;
a nonvolatile memory in which banks are set; and
a second write controller comprising bank writing modules corresponding to the banks, each bank writing module reading data written to one of the data buffer areas, and writing the read data to a corresponding bank of the nonvolatile memory,
wherein the first write controller is configured to write data transmitted from the host to a data buffer area in the data buffer areas from which first data written to the data buffer area is read when one of the bank writing modules reads the first data, and
each bank writing module is configured to read second data from one of the data buffer areas independently of data write processing statuses of another bank writing module, and to write the second data to a corresponding bank.

2. The device of claim 1, wherein
first host index numbers are stored in the buffer memory, the number of the first host index numbers being twice the number of banks,
first nonvolatile memory index numbers are stored in the buffer memory, the first nonvolatile memory index numbers are divisionally stored in the number of banks of blocks, the first nonvolatile memory index numbers being equal in number to the first host index numbers, and second nonvolatile memory index numbers stored in each block correspond to one of the bank writing modules,
buffer pointer storage areas are set in the buffer memory, a data buffer number indicating one of the data buffer areas is stored in some of buffer pointer storage areas, the buffer pointer storage areas being equal in number to the first host index numbers, and each first host index number and each first nonvolatile memory index number are associated with each buffer pointer storage area,
the first write controller comprises a first memory configured to store a first write pointer indicating a second host index number included in the first host index numbers,
the first write controller is configured to write third data to a data buffer area indicated by a data buffer number stored in a buffer pointer storage area associated with the second host index number, based on the first write pointer, and then to set a value of the first write pointer to a value indicating a next host index number of the second host index number,
the second write controller comprises a second memory configured to store a first registration pointer for indicating the second host index number,
each bank writing module comprises a third memory configured to store a first read pointer indicating a corresponding third nonvolatile memory index number in a first block in the blocks, and
each bank writing module is configured to read fourth data from a data buffer area indicated by a data buffer number stored in a first buffer pointer storage area indicated by a third nonvolatile memory index number indicated by the first read pointer, to write the fourth data to a corresponding bank, to store, in the first buffer pointer storage area, a data buffer number corresponding to the data buffer area in which the fourth data is stored, to set a value of the first registration pointer to a value indicating a next host index number of the second host index number, to free the first buffer pointer storage area, and to set a value of the first read pointer to a value indicating a corresponding nonvolatile memory index number in a block next to the first block.

3. The device of claim 2, wherein
free pointer-pointer storage areas are associated with the buffer pointer storage areas respectively, each free pointer-pointer storage area is configured to store a pointer of free pointer, the pointer of free pointer indicates a free pointer storage area, and a free pointer storage area is configured to store a data buffer number,
each bank writing module is configured to store the pointer of free pointer in the free pointer-pointer storage area associated with the buffer pointer storage area when a data buffer number is stored in the buffer pointer storage area,
the first write controller is configured to write third data to a data buffer area indicated by a data buffer number stored in a free pointer storage area indicated by the pointer of free pointer when the pointer of free pointer is stored in a free pointer-pointer storage area associated with a buffer pointer storage area indicated by the first write pointer, and
each bank writing module is configured to store, in the first buffer pointer storage area, a data buffer number stored in the first free pointer storage area, thereby freeing the free pointer storage area when the pointer of free pointer is stored in a free pointer- pointer storage area associated with the buffer pointer storage area.

4. The device of claim 1, further comprising:
a disk storage medium; and
a cache controller configured to use the nonvolatile memory as a cache of the disk storage medium.

5. A controller connected to a buffer memory and a nonvolatile memory, comprising:
a first write controller configured to sequentially write data transmitted from a host to data buffer areas set in the buffer memory; and
bank writing modules corresponding to banks set in the nonvolatile memory, each bank writing module configured to read data written to one of the data buffer areas, and to write the read data to a corresponding bank of the nonvolatile memory,
wherein the first write controller is configured to write data transmitted from the host to a data buffer area in the data buffer areas from which first data written to the data buffer area is read when one of the bank writing modules reads the first data, and
each bank writing module is configured to read second data from one of the data buffer areas independently of data write processing statuses of other bank writing modules, and to write the second data to a corresponding bank.

6. A data write method of a memory device connected to a buffer memory and a nonvolatile memory, the method comprising:
sequentially writing, by a write controller, data transmitted from a host to the data buffer areas set in the buffer memory; and
writing, by bank writing modules, data stored in the data buffer areas, to banks set in the nonvolatile memory, wherein
the sequentially writing comprises writing, by the write controller, data transmitted from the host to a data buffer area in the data buffer areas from which first data written to one of the data buffer areas is read when one of the bank writing modules reads the first data, and
the writing by bank writing modules comprises reading, by each bank writing module, second data from one of the data buffer areas independently of data write processing statuses of another bank writing module, and writing the second data to a corresponding bank.
